(19) United States
(12) Patent Application Publication
(10) Pub. No.: US 2022/0350571 A1
(43) Pub. Date: Nov. 3, 2022

(54) INFORMATION PROCESSING DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Takayuki IKEDA, Atsugi, Kanagawa (JP); Tatsuya ONUKI, Atsugi, Kanagawa (JP); Hitoshi KUNITAKE, Isehara, Kanagawa (JP)

(21) Appl. No.: 17/778,134

(22) PCT Filed: Nov. 25, 2020
(86) PCT No.: PCT/IB2020/061114

§ 371 Date: May 19, 2022

(30) Foreign Application Priority Data
Dec. 6, 2019 (JP) 2019-221080
Dec. 27, 2019 (JP) 2019-238714

(51) Int. Cl. G06F 7/544; G11C 11/405; G11C 11/4096; H01L 27/108; H01L 27/12; H01L 29/786

(52) U.S. Cl. CPC G06F 7/5443; G11C 11/405; G11C 11/4096; H01L 27/108; H01L 27/1207; H01L 27/1225; H01L 27/1255; H01L 29/7869

(57) ABSTRACT

A novel information processing device with least signal transmission delay and low power consumption is provided. A storage device includes a first layer, a second layer, and a third layer. The first layer is provided with a circuit. The second layer is provided with a memory cell portion. The third layer is provided with a first electrode. The circuit has a function of switching and performing reading or writing of first data or second data from or to the memory cell portion. At least part of the second layer is stacked above the first layer. At least part of the third layer is stacked above the second layer. An arithmetic device includes a fourth layer and a fifth layer. The fourth layer is provided with a central processing device. The fifth layer is provided with a second electrode. At least part of the fifth layer is stacked above the fourth layer. The circuit is electrically connected to the central processing device through the first electrode and the second electrode.

### TECHNICAL FIELD

The present invention relates to an information processing device. In particular, the present invention relates to an information processing device including a storage device utilizing semiconductor characteristics (also referred to as a semiconductor storage device or a memory) and an arithmetic device.

Note that one embodiment of the present invention is not limited to the above technical field. Examples of the technical field of one embodiment of the present invention disclosed in this specification and the like include a semiconductor device, an imaging device, a display device, a light-emitting device, a power storage device, a storage device, a display system, an electronic device, a lighting device, an input device, an input/output device, a driving method thereof, and a manufacturing method thereof.

### BACKGROUND ART

Hard disc drives (HDDs) have mainly been used for a long time as nonvolatile storage devices used for information processing devices such as a personal computer (PC), a server, and a data center. In recent years, solid state drives (SSDs) that are lightweight, have no physical operation portions, and perform high-speed data reading and writing have been widely spreading.

Many SSDs are formed using a NAND universal memory (also referred to as a flash memory) and a controller. A NAND universal memory is a nonvolatile storage device that stores data electrically. A DRAM (Dynamic Random Access Memory), an SRAM (Static RAM), or the like is used as a cache memory of an SSD. A DRAM and an SRAM are volatile storage devices. Note that in this specification and the like, a storage device utilizing semiconductor characteristics, such as a DRAM, an SRAM, or a NAND universal memory, is referred to as a semiconductor storage device (also referred to as a memory).

Meanwhile, a transistor including an oxide semiconductor or a metal oxide in a channel formation region (also referred to as an oxide semiconductor (OS) transistor) is known. The OS transistor has a feature of an extremely low drain current in an off state (the current is also referred to as an off-state current) (for example, see Non-Patent Document 1 and Non-Patent Document 2), which has been attracting attention. The DRAM is a storage device that includes memory cells each being composed of one transistor and one capacitor and stores data by accumulating charge in the capacitor. Therefore, when the OS transistor is used in the memory cell of the DRAM, stored data can be retained for a long time.

In addition, a CAAC (c-axis aligned crystalline) structure and an nc (nanocrystalline) structure, which are neither single crystal nor amorphous, have been found in an oxide semiconductor (see Non-Patent Document 1 and Non-Patent Document 3). Non-Patent Document 1 and Non-Patent Document 3 also disclose a technique for fabricating a transistor using an oxide semiconductor having a CAAC structure.

### REFERENCES

### Non-Patent Documents

[Non-Patent Document 1] S. Yamazaki et al., “Properties of crystalline In—Ga—Zn-oxide semiconductor and its transistor characteristics”, Jpn. J. Appl. Phys., vol. 53, 04ED18 (2014).
[Non-Patent Document 2] K. Kato et al., “Evaluation of Off-State Current Characteristics of Transistor Using Oxide Semiconductor Material, Indium-Gallium-Zinc Oxide”, Jpn. J. Appl. Phys., vol. 51, 021201 (2012).
[Non-Patent Document 3] S. Yamazaki et al., “SID Symposium Digest of Technical Papers”, 2012, volume 43, issue 1, pp. 183-186.
[Non-Patent Document 4] S. Maeda et al., “A 20 ns-Write 45 ns-Read and 10¹⁴-Cycle Endurance Memory Module Composed of 60 nm Crystalline Oxide Semiconductor Transistors”, ISSCC 2018, SESSION 30, EMERGING MEMORIES, 30.4, pp. 484-486.

### SUMMARY OF THE INVENTION

### Problems to be Solved by the Invention

Semiconductor storage devices such as DRAMs, SRAMs, NAND universal memories are fabricated in a process separate from that for a central processing unit (CPU). The semiconductor storage device and the CPU are connected through a limited number of wirings and accordingly, the need for high-speed data transmission based on the DIMM (Dual Inline Memory Module) standard or the like arises. A long distance between the semiconductor storage device and the CPU leads to high parasitic capacitance or high resistance of a wiring, which might increase power consumption.

A NAND universal memory as a semiconductor storage device needs a high voltage in writing and erasing. Moreover, a NAND universal memory is difficult to fabricate on the same chip as a cache memory such as a DRAM or an SRAM because of their fabrication processes being different from each other.

An object of one embodiment of the present invention is to provide an information processing device in which a NAND semiconductor storage device and a CPU can be connected through a short wiring. Another object of one embodiment of the present invention is to provide an information processing device in which power consumption can be reduced. Another object of one embodiment of the present invention is to provide an information processing device with a novel configuration in which the speeds of writing data and reading data in a NAND semiconductor storage device can be switched. Another object of one embodiment of the present invention is to provide an information processing device with a novel configuration.

Note that one embodiment of the present invention does not necessarily have to achieve all the above-described objects and only needs to achieve at least one of the objects. The descriptions of the above objects do not preclude the existence of other objects. Objects other than these will be apparent from the descriptions of the specification, the claims, the drawings, and the like, and objects other than these can be derived from the descriptions of the specification, the claims, the drawings, and the like.

### Means for Solving the Problems

One embodiment of the present invention is an information processing device which includes a storage device and an arithmetic device and in which the storage device includes a first layer and a second layer; the first layer is provided with a circuit; the second layer is provided with a memory cell portion; the circuit has a function of switching and performing reading or writing of first data or second data from or to the memory cell portion; the memory cell portion has a function of retaining the first data or the second data stored, without power supply; at least part of the second layer is stacked above the first layer; the arithmetic device is provided in the first layer; the arithmetic device includes a central processing device and an accelerator; and the accelerator execute a product-sum operation for performing inference processing based on a neural network.

In the information processing device of one embodiment of the present invention, it is preferable that the circuit include a data writing circuit and a data reading circuit, the data writing circuit include a first writing circuit which is configured to write the first data and a second reading circuit which is configured to write the second data, and the data reading circuit include a first reading circuit which is configured to read the first data and a second reading circuit which is configured to read the second data.

In the information processing device of one embodiment of the present invention, it is preferable that the first data be binary data and the second data be data having three or more values.

In the information processing device of one embodiment of the present invention, it is preferable that the first layer include an SOI substrate, the circuit include a first transistor formed on the SOI substrate, the memory cell portion include a second transistor, and the second transistor include a metal oxide in a channel formation region.

In the information processing device of one embodiment of the present invention, it is preferable that the first layer include a single crystal silicon substrate, the circuit include a first transistor formed on the single crystal silicon substrate, the memory cell portion include a second transistor, and the second transistor include a metal oxide in a channel formation region.

One embodiment of the present invention is a supercomputer which includes the above information processing device and a plurality of switchboards and in which the information processing device is electrically connected to the plurality of switchboards.

### Effect of the Invention

According to one embodiment of the present invention, an information processing device in which a NAND semiconductor storage device and a CPU can be connected through a short wiring can be provided. According to one embodiment of the present invention, an information processing device in which power consumption can be reduced can be provided. According to one embodiment of the present invention, an information processing device with a novel configuration in which the speeds of writing data and reading data in a NAND semiconductor storage device can be switched can be provided. According to one embodiment of the present invention, an information processing device with a novel configuration can be provided.

Note that one embodiment of the present invention does not necessarily have to achieve all the above-described objects and only needs to achieve at least one of the objects. The descriptions of the above objects do not preclude the existence of other objects. Objects other than these will be apparent from the descriptions of the specification, the claims, the drawings, and the like, and objects other than these can be derived from the descriptions of the specification, the claims, the drawings, and the like.

### BRIEF DESCRIPTION OF THE DRAWINGS

FIG. 1A and FIG. 1B are schematic perspective views showing a structure example of an information processing device.

FIG. 2 is a block diagram showing a configuration example of an information processing device.

FIG. 3 is a block diagram showing a configuration example of an information processing device.

FIG. 4A is a circuit diagram showing a configuration example of a string. FIG. 4B to FIG. 4E are circuit diagrams each showing a configuration example of a storage element.

FIG. 5A to FIG. 5D are circuit diagrams each showing a configuration example of a storage element.

FIG. 6A is a timing chart illustrating a writing operation. FIG. 6B is a timing chart illustrating a reading operation.

FIG. 7A and FIG. 7B are block diagrams showing configuration examples of an information processing device.

FIG. 8A and FIG. 8B are diagrams each showing a hierarchy of a variety of information processing devices.

FIG. 9 is a schematic perspective view showing a configuration example of an information processing device.

FIG. 10A and FIG. 10B are schematic perspective views showing a structure example of an information processing device.

FIG. 11A and FIG. 11B are a block diagram and a schematic perspective view showing a structure example of an information processing device.

FIG. 12 is a schematic perspective view and a block diagram showing a structure example of an information processing device.

FIG. 13 is a block diagram showing a configuration example of an information processing device.

FIG. 14A and FIG. 14B are schematic perspective views showing a structure example of an information processing device.

FIG. 15A to FIG. 15C are block diagrams each showing a structure example of an information processing device.

FIG. 16 is a cross-sectional view showing structure examples of transistors.

FIG. 17 is a diagram illustrating a configuration example of an information processing device.

FIG. 18A and FIG. 18B are diagrams illustrating an application example of an integrated circuit.

FIG. 19A is a perspective view showing an example of a semiconductor wafer. FIG. 19B is a perspective view showing an example of a chip. FIG. 19C and FIG. 19D are perspective views showing examples of electronic components.

FIG. 20A to FIG. 20J are each a perspective view or a schematic view illustrating an example of an electronic device.

FIG. 21A to FIG. 21E are each a perspective view or a schematic view illustrating an example of an electronic device.

FIG. 22A to FIG. 22C are diagrams illustrating examples of electronic devices.

FIG. 23 is a diagram illustrating an example of an electronic device.

FIG. 24 is a conceptual diagram of factory automation.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the terms do not limit the number of components. Furthermore, the terms do not limit the order of components. In this specification and the like, for example, a “first” component in one embodiment can be referred to as a “second” component in other embodiments or claims. For another example, a “first” component in one embodiment in this specification and the like can be omitted in other embodiments or claims.

The same components, components having similar functions, components made of the same material, components formed at the same time, and the like in the drawings are denoted by the same reference numerals, and repeated description thereof is skipped in some cases.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “[n]”, or “[m,n]” is sometimes added to the reference numerals. For example, the second wiring GL is referred to as a wiring GL[2].

### Embodiment 1

In this embodiment, structure examples of an information processing device of one embodiment of the present invention will be described.

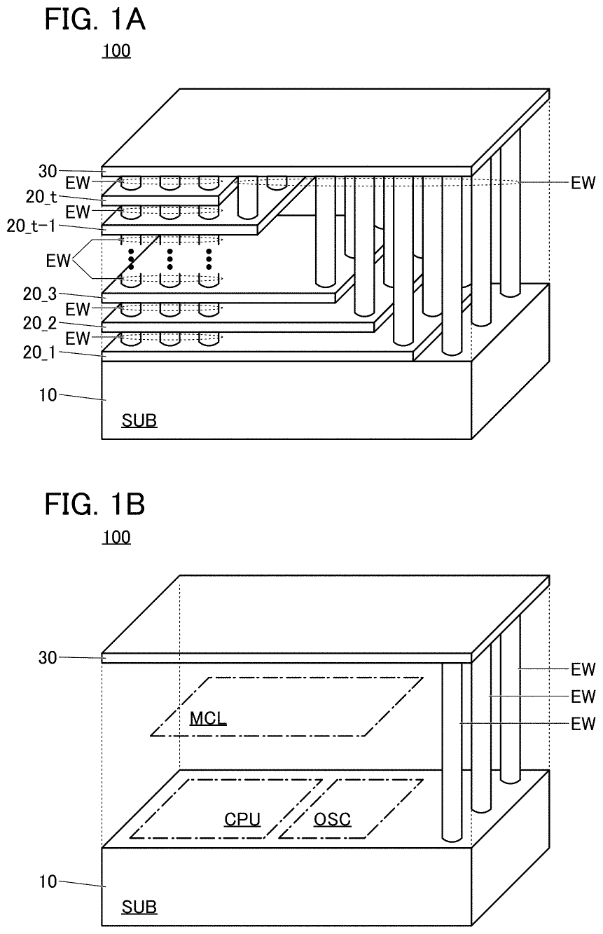

FIG. 1A is a schematic perspective view showing a structure example of an information processing device 100 of one embodiment of the present invention. The information processing device 100 includes a layer 10, a layer 20_1 to a layer 20_t (t is an integer greater than or equal to 2), a layer 30, and wirings EW. The wiring EW corresponds to a member provided in an opening that is provided from an upper layer to a lower layer, e.g., a member constituting a storage element or an electrode such as a plug.

As shown in FIG. 1A, the information processing device 100 has a structure in which at least part of the layer 20_1 is stacked above the layer 10, at least part of a layer 20_k+1 is stacked above a layer 20_k (k is an integer greater than or equal to 1 and less than or equal to l−1), and at least part of the layer 30 is stacked above the layer 20_t.

In the information processing device 100, the layer 10, the layer 20_1 to the layer 20_t, and the layer 30 define a storage device, and the layer 10 defines an arithmetic device. Here, the storage device can be, for example, a NAND OS memory including a three-dimensional OS transistor. Note that an OS transistor is a transistor including a metal oxide in a channel formation region.

The layer 10, the layer 20_1 to the layer 20_t, and the layer 30 are provided with circuits that can function by utilizing semiconductor characteristics. The layer 10 is provided with a circuit OSC and a circuit CPU which will be described later. The layer 20_1 to the layer 20_t are provided with a memory cell portion MCL which will be described later. The layer 30 is a wiring layer where wirings are formed. The above-described storage device corresponds to the memory cell portion MCL. The above-described arithmetic device corresponds to the circuit OSC and the circuit CPU.

FIG. 1B is a schematic perspective view in which the layer 20_1 to the layer 20_t and the wirings EW connected to the layers 20 are omitted from FIG. 1A and which illustrates the positional relationships between the circuit OSC, the circuit CPU, and the memory cell portion MCL. Note that in the drawings described in this specification and the like, the flow of main signals is indicated by an arrow or a line, and a power supply line and the like are omitted in some cases.

The circuit OSC has a function of a driver circuit or a control circuit of the memory cell portion MCL. The circuit OSC includes a writing circuit, a reading circuit, and the like. The circuit OSC writes and reads data to and from a plurality of storage elements (memory cells) provided in the layer 20_1 to the layer 20_t in the memory cell portion MCL.

The circuit CPU has a function of performing arithmetic processing of data written to the memory cell portion MCL or data read from the memory cell portion MCL. The arithmetic processing of the data is performed by an arithmetic circuit and the like included in the circuit CPU. The circuit CPU is also referred to as a central processing unit or a central processing device.

The circuit OSC and the circuit CPU are formed using transistors formed on a substrate SUB. For example, a single crystal semiconductor substrate or a polycrystalline semiconductor substrate using silicon, silicon carbide, or the like as a material or a compound semiconductor substrate using silicon germanium or the like as a material can be used as the substrate SUB. Furthermore, an SOI substrate, a semiconductor substrate over which a semiconductor element such as a strained transistor or a FIN-type transistor is provided, a glass substrate of barium borosilicate glass, aluminoborosilicate glass, or the like, a ceramic substrate, a quartz substrate, a sapphire substrate, or the like may be used as the substrate SUB. Alternatively, a flexible substrate may be used as the substrate SUB. In this embodiment, a case in which a single crystal silicon substrate is used as the substrate SUB is described. Note that a transistor including silicon in a channel formation region is referred to as a Si transistor.

The circuit OSC and the memory cell portion MCL are electrically connected to each other through the wirings EW and the layer 30. The wiring EW has a function of electrically connecting the circuit OSC and the layer 30, and a function of electrically connecting the memory cells included in the memory cell portion MCL and the layer 30. Note that the wiring EW can be one or more kinds of wirings selected from a signal line, a power supply line for supplying a constant potential, a bit line (e.g., a write bit line or a read bit line), a word line, and the like.

The circuit OSC and the circuit CPU are electrically connected to each other with the use of a wiring formed on the substrate SUB. The data transfer distance between the circuit OSC, the circuit CPU, and the memory cell portion MCL in the information processing device 100 is short, allowing the information processing device 100 to have features such as least signal transmission delay, a resultant high-speed operation, and a minimized increase in power consumption due to parasitic capacitance or the like. The memory cell portion MCL is provided to overlap with and to be above the circuit OSC and the circuit CPU, thereby inhibiting an increase in the circuit area of the information processing device 100.

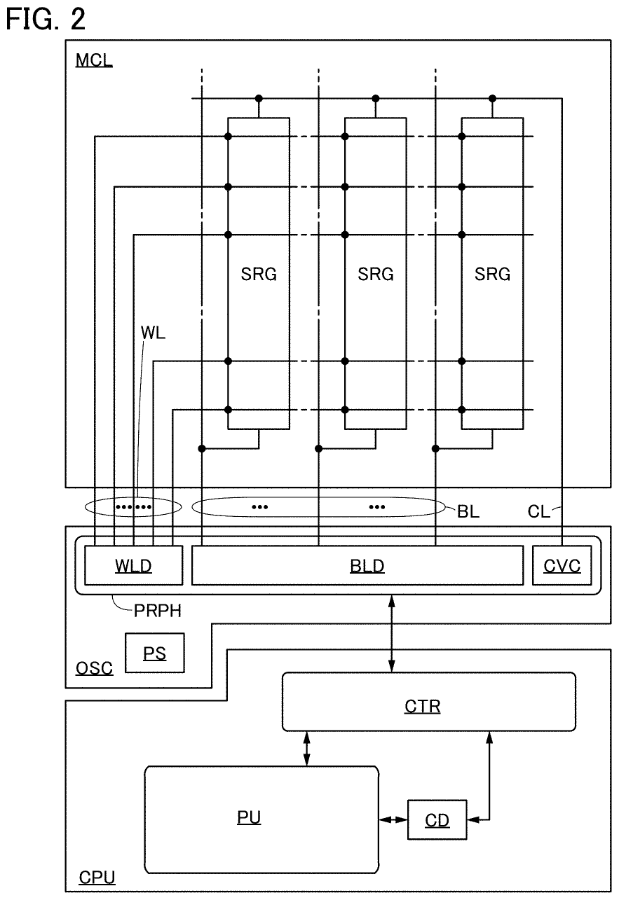

Next, a configuration example of the circuit CPU, the circuit OSC, and the memory cell portion MCL is described. FIG. 2 is a block diagram showing the configuration example of the circuit CPU, the circuit OSC, and the memory cell portion MCL.

The memory cell portion MCL includes a memory cell array provided with a plurality of strings SRG. The strings SRG are electrically connected to wirings BL.

A channel formation region of each of the transistors included in the memory cell of the string SRG preferably contains any one or more materials selected from, for example, silicon, germanium, gallium arsenide, silicon carbide (SiC), and a metal oxide.

Particularly in the case where the channel formation region contains a metal oxide of one or more selected from indium, an element M (e.g., aluminum, gallium, yttrium, or tin can be given as the element M), and zinc, the metal oxide sometimes functions as a wide gap semiconductor; thus, the transistor including the metal oxide in the channel formation region has extremely low off-state current characteristics. That is, the leakage current of the transistor in an off state can be reduced, so that stored data can continue to be retained without power supply. This can reduce the power consumption of the information processing device in some cases. In addition, an analog potential corresponding to retained data can be retained and thus, binary (1-bit) data or multilevel (multi-bit) data having three or more values can be retained.

Wirings WL, the wirings BL, and a wiring CL shown in FIG. 2 correspond to the wirings EW shown in FIG. 1A and FIG. 1B. The wirings WL, which are a plurality of word lines, are electrically connected to the storage elements included in the string SRG row by row. The wirings BL, which are a plurality of bit lines, are electrically connected to the storage elements included in the string SRG column by column. The wiring CL is a power supply line.

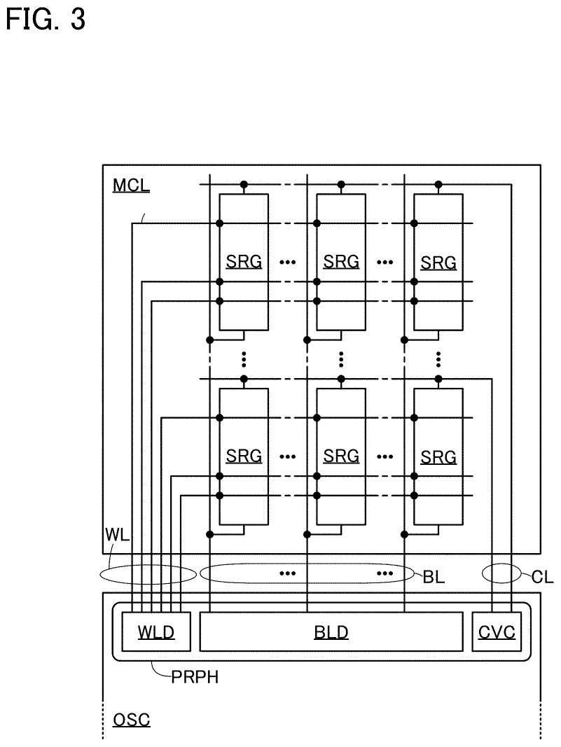

Although one wiring BL is electrically connected to one string SRG in the memory cell portion MCL in FIG. 2, one embodiment of the present invention is not limited thereto. For example, the memory cell portion MCL may have a structure in which one wiring BL is electrically connected to a plurality of strings SRG as illustrated in FIG. 3. Note that the block diagram of FIG. 3 illustrates the memory cell portion MCL and part of the circuit OSC.

The circuit OSC includes, for example, a circuit PRPH and a power supply circuit PS. The circuit CPU includes, for example, a command decoder CD and an arithmetic circuit PU. Although one arithmetic circuit PU is illustrated, a plurality of arithmetic circuits PU may be provided to enable a multicore configuration.

The circuit CPU includes a control circuit CTR. The control circuit CTR and the command decoder CD of the circuit CPU are not clearly discriminated. In other words, the control circuit CTR can have a part common to the circuit CPU. The control circuit CTR has a function of accessing the circuit PRPH to write data to the memory cell portion MCL and to read out data from the memory cell portion MCL. Furthermore, the control circuit CTR has a function of accessing the arithmetic circuit PU and the command decoder CD to enable input and output of data.

The control circuit CTR, upon input of a write instruction and data, writes the data to the memory cell portion MCL as binary data. Then, the written binary data can be read out from the memory cell portion MCL, and the read data can be written to the memory cell portion MCL as multilevel data. That is, the memory cell portion MCL has a function of a cache memory for the memory cell portion MCL. The control circuit CTR may have a function of writing multilevel data directly to the memory cell portion MCL in the case where the memory access frequency is low, for example.

The control circuit CTR, upon input of a read instruction, reads out binary data or multilevel data from the memory cell portion MCL and outputs the data to the arithmetic circuit PU and the command decoder CD as binary data. To and from the arithmetic circuit PU and the command decoder CD, data that has been converted into a digital signal can be input and output. Note that the write instruction and the read instruction each include an address signal.

The control circuit CTR may have a function of detecting and correcting an error (also referred to as ECC: Error Check and Correct) in reading out data from the memory cell portion MCL. The memory cell portion MCL can also function as a cache memory when the control circuit CTR detects and corrects an error. The signals processed by the control circuit CTR and the functions of the control circuit CTR are not limited to the above; a different signal may be input (or output) as necessary, and the control circuit CTR may have a different function.

The control circuit CTR can read out the data that has been written as the binary data or multilevel data from the memory cell portion MCL through the wiring EW. The read data can be written to the memory cell portion MCL again through the wiring EW. The signal that is input and output between the memory cell portion MCL and the circuit CPU transfers through the wiring EW, allowing the data transfer distance to be short. Note that the number of wirings transmitting the signal that is input and output between the memory cell portion MCL and the circuit CPU is preferably greater than or equal to 75.

The memory cell portion MCL of the information processing device 100 can be used as a cache memory. The data transfer distance between the memory cell portion MCL and the circuit OSC and that between the circuit OSC and the circuit CPU are short. This allows for features such as least signal transmission delay, a resultant high-speed operation, and a minimized increase in power consumption due to parasitic capacitance or the like.

The circuit PRPH includes a circuit WLD, a circuit BLD, and a circuit CVC, for example. The circuit WLD functions as a word line driver circuit and is electrically connected to the wirings WL. The circuit BLD functions as a bit line driver circuit and is electrically connected to the wirings BL. The circuit CVC functions as a power source that generates a constant potential and outputs the constant potential, and is electrically connected to the wiring CL.

The circuit CPU includes, as components other than the control circuit CTR, the command decoder CD and the arithmetic circuit PU, for example. Although one arithmetic circuit PU is illustrated, a plurality of arithmetic circuits PU may be provided to enable a multicore configuration. The command decoder CD generates a memory address when a command is the one for reading data. The memory address is supplied to the circuit OSC. The circuit OSC reads out data from the memory cell portion MCL by controlling the circuit PRPH. The read data is supplied to the arithmetic circuit PU. When a command to the command decoder CD is the one for writing data, data is transferred from a memory cell in the memory cell portion MCL or a register in the arithmetic circuit PU to a memory cell of the memory cell portion MCL. The transferred data may be subjected to arithmetic processing by passing through the arithmetic circuit PU. The generated memory address can be not only converted from a logic address into a physical address but also converted in a manner to avoid a defective block. The circuit CPU has a function of enabling a normally-off operation. The value of a register in the circuit CPU is written to the memory cell portion MCL through the circuit OSC at the time of backup of data in the register in the arithmetic circuit PU.

Next, a circuit configuration example of the string SRG included in the memory cell portion MCL is described.

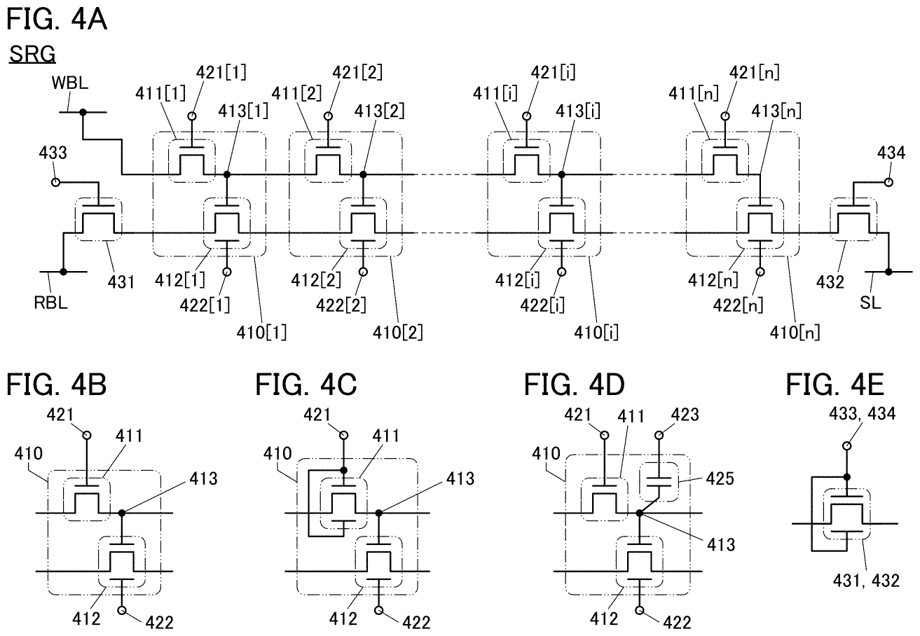

FIG. 4A shows a circuit diagram of the string SRG of the memory cell portion MCL. The string SRG includes a plurality of storage elements 410 between a transistor 431 and a transistor 432. FIG. 4B shows a circuit diagram of the storage element 410. The storage element 410 includes a transistor 411 and a transistor 412.

In this embodiment and the like, the first storage element 410 is denoted as a storage element 410[1] and the n-th (n is an integer greater than or equal to 3) storage element 410 is denoted as a storage element 410[n]. The i-th (i is an integer greater than or equal to 2 and less than n) storage element 410 is denoted as a storage element 410[i]. Note that the “storage element 410” may be simply used in the case of description common to the storage element 410[1] to the storage element 410[n].

In this embodiment and the like, the transistor 411 included in the first storage element 410 is denoted as a transistor 411[1], the transistor 411 included in the i-th storage element 410 is denoted as a transistor 411[i], and the transistor 411 included in the n-th storage element 410 is denoted as a transistor 411[n]. Note that the “transistor 411” may be simply used in the case of description common to the transistor 411[1] to the transistor 411[n]. The transistor 412, a node 413 described later, and the like are also denoted in a manner similar to that of the transistor 411.

The circuit configuration example of the string SRG shown in FIG. 4A is described in detail. One of a source and a drain of the transistor 411[1] included in the storage element 410[1] is electrically connected to a wiring WBL, and the other is electrically connected to a node 413[1]. A gate of the transistor 411[1] is electrically connected to a terminal 421[1]. One of a source and a drain of a transistor 412[1] is electrically connected to the other of a source and a drain of the transistor 431 and the other is electrically connected to one of a source and a drain of a transistor 412[2]. Agate of the transistor 412[1] is electrically connected to the node 413[1]. Aback gate of the transistor 412[1] is electrically connected to a terminal 422[1].

One of the source and the drain of the transistor 431 is electrically connected to a wiring RBL and the other is electrically connected to the one of the source and the drain of the transistor 412[1]. A gate of the transistor 431 is electrically connected to a terminal 433. Note that the wiring WBL and the wiring RBL correspond to the wirings BL shown in FIG. 2; the wiring WBL is used in data writing, and the wiring RBL is used in data reading.

One of a source and a drain of a transistor 411[2] included in a storage element 410[2] is electrically connected to the node 413[1], and the other is electrically connected to a node 413[2]. A gate of the transistor 411[2] is electrically connected to a terminal 421[2]. The one of the source and the drain of the transistor 412[2] is electrically connected to the other of the source and the drain of the transistor 412[1], and a gate of the transistor 412[2] is electrically connected to the node 413[2]. A back gate of the transistor 412[2] is electrically connected to a terminal 422[2].

One of a source and a drain of the transistor 411[i] included in the storage element 410[i] is electrically connected to a node 413[i−1] (not illustrated), and the other is electrically connected to a node 413[i]. A gate of the transistor 411[i] is electrically connected to a terminal 421[i]. One of a source and a drain of a transistor 412[i] is electrically connected to one or the other of a source and a drain of a transistor 412[i−1] (not illustrated). A gate of the transistor 412[i] is electrically connected to the node 413[i] and a back gate of the transistor 412[i] is electrically connected to a terminal 422[i].

One of a source and a drain of the transistor 411[n] included in the storage element 410[n] is electrically connected to a node 413[n−1] (not illustrated). The other of the source and the drain of the transistor 411[n] is electrically connected to a node 413[n]. A gate of the transistor 411[n] is electrically connected to a terminal 421[n].

One of a source and a drain of a transistor 412[n] is electrically connected to one or the other of a source and a drain of a transistor 412[n−1] (not illustrated). The other of the source and the drain of the transistor 412[n] is electrically connected to the transistor 432. A gate of the transistor 412[n] is electrically connected to the node 413[n] and a back gate of the transistor 412[n] is electrically connected to a terminal 422[n].

One of a source and a drain of the transistor 432 is electrically connected to the other of the source and the drain of the transistor 412[n]. The other of the source and the drain of the transistor 432 is electrically connected to a wiring SL. A gate of the transistor 432 is electrically connected to a terminal 434.

The string SRG illustrated in FIG. 4A includes the n storage elements 410 between the transistor 431 and the transistor 432. The transistor 411[1] to the transistor 411[n] are connected in series while the source and the drain are shared by adjacent transistors. The transistor 412[1] to the transistor 412[n] are also connected in series while the source and the drain are shared by adjacent transistors.

Such a structure in which the storage elements 410 are connected while the source and the drain are shared by adjacent transistors is referred to as a “string”, a “cell string”, or a “memory cell string” in some cases. For example, one string SRG is sometimes referred to as “one string” or simply a “string”. Note that a “string”, a “cell string”, and a “memory cell string” are also used as units in some cases.

The storage element 410 (see FIG. 4B) has a function of retaining a potential (charge) written to the node 413. Specifically, a voltage for turning on the transistor 411 is supplied from the terminal 421 to a gate of the transistor 411, and charge for setting the node 413 to a predetermined voltage is supplied to the node 413 through a source and a drain of the transistor 411. Then, a voltage for turning off the transistor 411 is supplied from the terminal 421 to the gate of the transistor 411. The charge written to the node 413 can be retained when the transistor 411 is turned off.

For semiconductor layers of the transistor 411 and the transistor 412, a single crystal semiconductor, a polycrystalline semiconductor, a microcrystalline semiconductor, an amorphous semiconductor, or the like can be used alone or in combination. As a semiconductor material, silicon, germanium, or the like can be used. Alternatively, a compound semiconductor such as silicon germanium, silicon carbide, gallium arsenide, an oxide semiconductor, or a nitride semiconductor can be used. The same applies to the transistor 431 and the transistor 432.

Note that the semiconductor layers may be stacked in the transistor. In that case, the stacked semiconductor layers may include different semiconductor materials or semiconductors with different crystal states.

In particular, the transistor 411 is preferably an OS transistor. The oxide semiconductor has a band gap of 2 eV or more, achieving an extremely low off-state current. When the OS transistor is used as the transistor 411, the charge written to the node 413 can be retained for a long period. In the case where the OS transistor is used as the transistor 411, the storage element 410 can be referred to as an “OS memory”.

The OS memory can retain information written thereto for one year or longer, or ten years or longer even after power supply is stopped. Hence, the OS memory can be regarded as a nonvolatile memory.

Since the amount of charge written to the OS memory hardly changes for a long period, multilevel (multi-bit) data (information) as well as binary (1-bit) information can be retained in the OS memory.

Furthermore, an OS memory employs a method in which charge is written to a node through the OS transistor; hence, a high voltage, which a conventional NAND universal memory requires, is unnecessary and a high-speed writing operation is possible. The OS memory does not require an erasing operation that is performed in a NAND universal memory before data rewriting. Furthermore, the OS memory does not conduct charge injection and extraction to and from a floating gate or a charge-trap layer, substantially allowing an unlimited number of times of data writing and reading. The OS memory degrades less than a conventional NAND universal memory and can have high reliability.

Unlike a magneto-resistive memory (MRAM), a resistance-change memory (ReRAM), and the like, the OS memory does not undergo a structure change at the atomic level. Hence, the OS memory has higher rewrite endurance than the magneto-resistive memory and the resistance-change memory.

The off-state current of the OS transistor hardly increases even in a high-temperature environment. Specifically, the off-state current hardly increases even at an environment temperature of from room temperature to 200° C. In addition, the on-state current is unlikely to decrease even in a high-temperature environment. A storage device including the OS memory achieves a stable operation and high reliability even in a high-temperature environment. Furthermore, the withstand voltage between the source and the drain of the OS transistor is high. When OS transistors are used as transistors included in an OS memory, an information processing device can be obtained which achieves a stable operation and high reliability even in a high-temperature environment.

As shown in FIG. 4C, a transistor having a back gate may be used as the transistor 411 included in the storage element 410. FIG. 4C shows an example in which the gate and the back gate of the transistor 411 are electrically connected.

As shown in FIG. 4D, a capacitor 425 may be provided between the node 413 and a terminal 423. In the case where the capacitor 425 is provided, a fixed potential is preferably supplied to the terminal 423. When the capacitor 425 is provided, the potential change of the node 413 can be inhibited and the reliability of the string SRG can be increased. The storage element 410 is preferably provided with the capacitor 425 particularly when storing multilevel information.

As shown in FIG. 4E, a transistor having a back gate may be used as the transistors 431 and 432. FIG. 4E shows an example in which the gate and the back gate are electrically connected in each of the transistors 431 and 432.

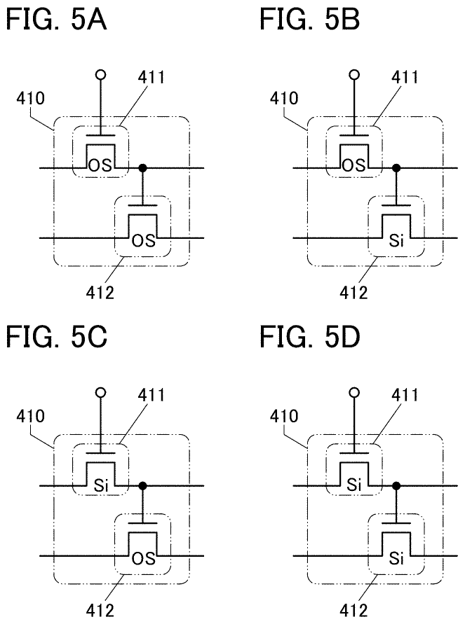

As shown in FIG. 5A, the transistors 411 and 412 included in the storage element 410 may each be an OS transistor. In FIG. 5A, the sign “OS” is added to each of the transistors 411 and 412 that are OS transistors.

Alternatively, the transistor 411 and the transistor 412, which are included in the storage element 410, may respectively be an OS transistor and a Si transistor as shown in FIG. 5B. In FIG. 5A, the sign “OS” is added to the transistor 411 that is an OS transistor, and the sign “Si” is added to the transistor 412 that is a Si transistor.

Alternatively, the transistor 411 and the transistor 412, which are included in the storage element 410, may respectively be a Si transistor and an OS transistor as shown in FIG. 5C. In FIG. 5C, the sign “Si” is added to the transistor 411 that is a Si transistor, and the sign “OS” is added to the transistor 412 that is an OS transistor.

As shown in FIG. 5D, the transistors 411 and 412 included in the storage element 410 may each be a Si transistor. In FIG. 5D, the sign “Si” is added to each of the transistors 411 and 412 that are Si transistors.

An operation example of the string SRG will be described with reference to drawings. In this embodiment, the description is made on an example of the string SRG which includes four storage elements 410.

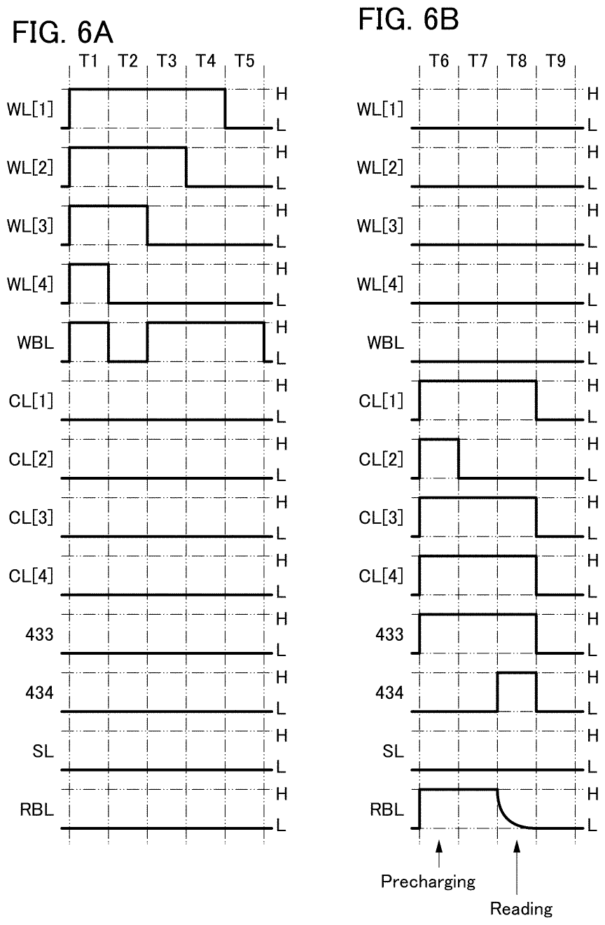

FIG. 6A is a timing chart illustrating a writing operation. FIG. 6A illustrates an operation example where an H potential is written to the storage element 410[1], the storage element 410[2], and a storage element 410[4] whereas an L potential is written to a storage element 410[3]. A wiring WL[1] to a wiring WL[4] correspond to wirings that are connected to the terminal 421 as shown in FIG. 4D. A wiring CL[1] to a wiring CL[4] correspond to wirings that are connected to the terminal 423 in the case where the capacitor 425 is provided between the node 413 and the terminal 423 as shown in FIG. 4D.

It is assumed that in the initial state, the L potential is written to the storage element 410[1] to the storage element 410[4]. It is also assumed that the L potential is supplied to the wiring WL[1] to the wiring WL[4], the wiring CL[1] to the wiring CL[4], the terminal 433, the terminal 434, the wiring SL, and the wiring RBL.

In Period T1, the H potential is supplied to the wiring WL[1] to the wiring WL[4] and the wiring WBL. Then, the node 413[1] to a node 413[4] have the H potential, so that the transistor 412[1] to a transistor 412[4] are turned on.

In Period T2, the L potential is supplied to the wiring WL[4]. Then, a transistor 411[4] is turned off and charge written to the node 413[4] is retained. Here, the charge equivalent to the H potential is retained. The L potential is supplied to the wiring WBL. Then, the node 413[1] to a node 413[3] have the L potential, so that the transistor 412[1] to a transistor 412[3] are turned off.

In Period T3, the L potential is supplied to a wiring WL[3]. Then, a transistor 411[3] is turned off and charge written to the node 413[3] is retained. Here, the charge equivalent to the L potential is retained. The H potential is supplied to the wiring WBL. Then, the node 413[1] and the node 413[2] have the H potential, so that the transistor 412[1] and the transistor 412[2] are turned on.

In Period T4, the L potential is supplied to a wiring WL[2]. Then, the transistor 411[2] is turned off and charge written to the node 413[2] is retained. Here, the charge equivalent to the H potential is retained.

In Period T5, the L potential is supplied to the wiring WL[1]. Then, the transistor 411[1] is turned off and charge written to the node 413[1] is retained. Here, the charge equivalent to the H potential is retained. In this manner, information can be written to the storage element 410[1] to the storage element 410[4].

FIG. 6B is a timing chart illustrating a reading operation. FIG. 6B illustrates an operation example of reading information retained in the storage element 410[2] among the information retained in the storage element 410[1] to the storage element 410[4]. It is assumed that the H potential is retained in the storage element 410[2].

In Period T6, the H potential is supplied to the wiring CL[1] to the wiring CL[4] and the terminal 433, so that the transistor 412[1] to the transistor 412[4] and the transistor 431 are turned on. Furthermore, the wiring RBL is precharged to the H potential, and the wiring RBL is brought into a floating state.

In Period T7, the L potential is supplied to a wiring CL[2]. Since the H potential is retained in the node 413[2], the transistor 412[2] remains on.

In Period T8, the H potential is supplied to the terminal 434, so that the transistor 432 is turned on. The transistor 412[1] to the transistor 412[4] are all on; accordingly, the wiring RBL and the wiring SL are electrically connected and the potential of the wiring RBL is changed to the L potential.

Note that in the case where the node 413[2] has the L potential, the transistor 412[2] is turned off when the L potential is supplied to the wiring CL[2]. In that case, the potential of the wiring RBL remains H even when the transistor 432 is turned on. What information is retained in the storage element 410 is known from a change in the potential of the wiring RBL.

That is, by setting the potential of the wiring CL corresponding to the storage element 410 of a reading target to the L potential in Period T7, the information retained in the storage element 410 can be read.

In Period T9, the L potential is supplied to the wiring CL[1] to the wiring CL[4], the terminal 433, and the terminal 434. Then, the transistor 412[1], the transistor 412[2], the transistor 412[4], the transistor 431, and the transistor 432 are turned off.

The memory cell portion MCL including the string SRG, which is described in this embodiment and the like, serves as a NAND storage device.

Note that data that is rewritten frequently is stored in the storage element 410 close to the wiring WBL, so that the data can be written (rewritten) in a shorter time. That is, the speed of writing (rewriting) data can be increased. With such an operation, a later-described 3D OS NAND can operate as a temporary storage device like a RAM.

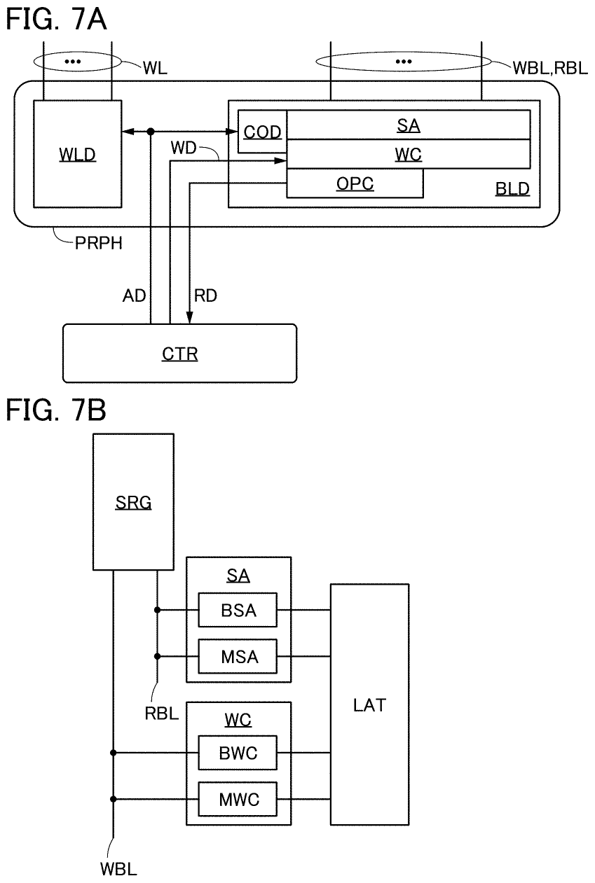

The circuit BLD included in the circuit OSC is specifically described. FIG. 7A is a block diagram illustrating a configuration example of part of the circuit OSC. FIG. 7A shows not only the circuit OSC but also the control circuit CTR of the circuit CPU. In FIG. 7A, the power supply circuit PS and the like are omitted from the circuit OSC shown in FIG. 2, and the configuration example of the circuit BLD and flow of signals in the circuit OSC are specifically shown.

The circuit BLD can have a structure including a column decoder COD, a writing circuit WC, a sense amplifier SA, and an output circuit OPC, for example.

The column decoder COD has a function of selecting, in accordance with an address signal AD obtained from the control circuit CTR, the wiring BL electrically connected to the storage element on which writing or reading is to be performed. Here, the address signal AD is an internal signal of the circuit OSC. The address signal AD is also transmitted to the circuit WLD. The circuit WLD has a function of driving the wiring WL and a function of selecting, in accordance with the address signal AD, the wiring WL electrically connected to the storage element on which writing or reading is to be performed.

The writing circuit WC has a function of supplying, to the wiring BL selected by the column decoder COD, a potential corresponding to a data signal WD supplied from the control circuit CTR. Here, the data signal WD is an internal signal of the circuit OSC.

The sense amplifier SA has a function of amplifying a data signal read out from the wiring BL. Note that the amplified data signal is output to the control circuit CTR through the output circuit OPC as a data signal RD. The control circuit CTR outputs a signal corresponding to the data signal RD to the arithmetic circuit PU or the command decoder CD.

Note that the components of the circuit BLD are not limited thereto; another component may be added if needed, or an unnecessary component may be omitted. The functions of the circuit BLD are not limited thereto; another function may be added, or an unnecessary function may be omitted.

FIG. 7B is a block diagram illustrating a configuration in which data is switched between binary data and multilevel data to be written to the string SRG and data is switched between binary data and multilevel data to be read out from the string SRG.

In FIG. 7B, the sense amplifier SA illustrated in FIG. 7A includes a binary data-specific sense amplifier BSA for reading binary data and a multilevel data-specific sense amplifier MSA for reading multilevel data. FIG. 7B shows a latch circuit LAT for temporarily retaining data. The binary data-specific sense amplifier BSA can be a writing circuit for a DRAM. The multilevel data-specific sense amplifier MSA can be, for example, an A/D converter circuit capable of converting an analog signal into a digital signal.

In FIG. 7B, the writing circuit WC illustrated in FIG. 7A includes a binary data-specific writing circuit BWC for writing binary data and a multilevel data-specific writing circuit MWC for writing multilevel data. The binary data-specific writing circuit BWC can be a writing circuit for a DRAM. The multilevel data-specific writing circuit MWC can be, for example, a D/A converter circuit capable of converting a digital signal into an analog signal.

The description is made on an operation at the time of performing high-speed writing and high-speed reading, e.g., an operation in the case where the string SRG is used as a cache memory. In the case where the command to be executed by the circuit CPU is stored in the form of multilevel data, the data is preliminarily made binary by instruction branch prediction or the like. The binary data is preliminarily read out from the circuit CPU in units of blocks of the string SRG and is temporarily stored in the latch circuit LAT. Of the binary data stored in the latch circuit LAT, the data having the value of an intended address can be transferred to the arithmetic circuit PU and the command decoder CD of the circuit CPU.

In data rewriting, data to be rewritten is read out to the latch circuit LAT in the case where the binary data in the latch circuit LAT does not have the value of the intended address. The value of the intended address is rewritten in the latch circuit LAT, and the data is written to the string SRG again. To rewrite the data in the storage element in an upper layer of the string SRG, data is copied in units of blocks of the string SRG. The capacity of the latch circuit LAT is not necessarily equal to the capacity of one block.

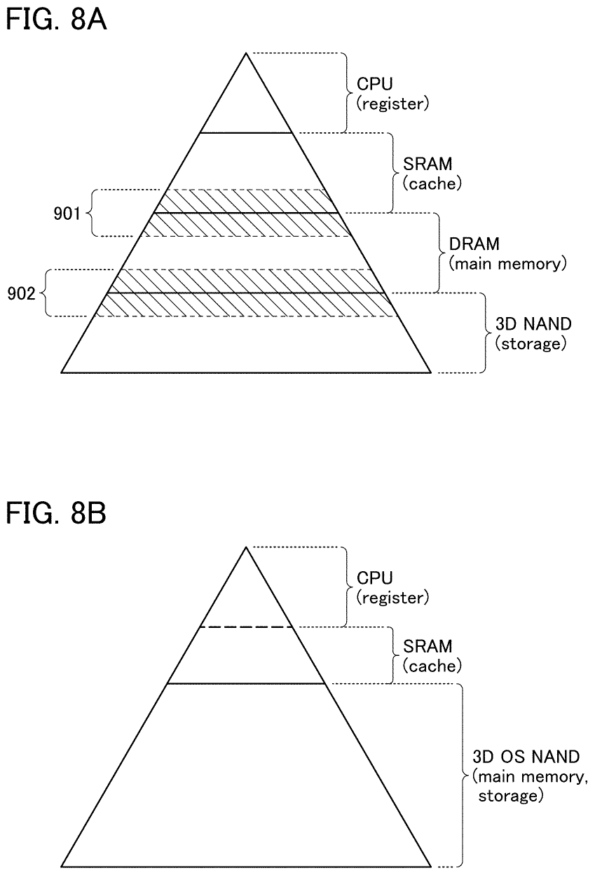

In general, a variety of storage devices are used in semiconductor devices such as computers in accordance with the intended use. FIG. 8A shows the hierarchy of various storage devices used in semiconductor devices. The storage devices at the upper levels require a higher operating speed, whereas the storage devices at the lower levels require a larger storage capacity and a higher recording density. FIG. 8A shows, sequentially from the top level, a memory included as a register in an arithmetic processing device such as a CPU, an SRAM, a DRAM, and a 3D NAND memory.

In this specification and the like, a three-dimensional NAND universal memory including an OS transistor is referred to as a “3D OS NAND”. A three-dimensional NAND universal memory including a Si transistor is referred to as a “3D NAND”. For example, the aforementioned information processing device 100 includes a storage device that is a 3D OS NAND.

In the 3D OS NAND, random access can be performed and the OS transistor has a characteristic of an off-state current being extremely small; thus, the 3D OS NAND can retain information written thereto for one year or longer, furthermore, for ten years or longer even after power supply is stopped. Hence, the 3D OS NAND can be regarded as a nonvolatile memory.

Since the amount of charge written to the 3D OS NAND hardly changes for a long period, multilevel (multi-bit) information as well as binary (1-bit) information can be retained in the 3D OS NAND.

Furthermore, the 3D OS NAND employs a method in which charge is written to a node through the OS transistor; hence, a high voltage, which a conventional NAND universal memory requires, is unnecessary and a high-speed writing operation is possible. The 3D OS NAND does not require an erasing operation that is performed in a NAND universal memory before data rewriting. Furthermore, the 3D OS NAND does not conduct charge injection and extraction to and from a floating gate or a charge-trap layer, substantially allowing an unlimited number of times of data writing and reading. The 3D OS NAND degrades less than a conventional NAND universal memory and can have high reliability.

Unlike a magneto-resistive memory (MRAM), a resistance-change memory (ReRAM), and the like, the 3D OS NAND does not undergo a structure change at the atomic level. Hence, the 3D OS NAND has higher rewrite endurance than the magneto-resistive memory and the resistance-change memory.

The off-state current of the OS transistor hardly increases even in a high-temperature environment. Specifically, the off-state current hardly increases even at an environment temperature of from room temperature to 200° C. In addition, the on-state current is unlikely to decrease even in a high-temperature environment. A storage device including the OS memory achieves a stable operation and high reliability even in a high-temperature environment. Furthermore, the withstand voltage between the source and the drain of the OS transistor is high. When OS transistors are used as transistors included in a 3D OS NAND, an information processing device can be obtained which achieves a stable operation and high reliability even in a high-temperature environment.

A memory included as a register in an arithmetic processing device such as a CPU is used for temporary storage of arithmetic operation results, for example, and thus is very frequently accessed by the arithmetic processing device. Accordingly, a high operating speed is required rather than storage capacity. The register also has a function of retaining settings of the arithmetic processing device, for example.

An SRAM is used for a cache, for example. The cache has a function of duplicating and retaining part of data retained in a main memory. By duplicating frequently used data and retaining the duplicated data in the cache, the access speed to the data can be increased. The cache requires a smaller storage capacity than the main memory but requires a higher operating speed than the main memory. Data that is rewritten in the cache is duplicated, and the duplicated data is supplied to the main memory.

A DRAM is used for the main memory, for example. The main memory has a function of retaining a program, data, and the like that are read from the storage. The recording density of a DRAM is approximately 0.1 to 0.3 Gbit/mm².

A 3D NAND memory is used for the storage, for example. The storage has a function of retaining data that needs to be stored for a long period and various programs used in an arithmetic processing device, for example. Therefore, the storage needs to have a large storage capacity and a high recording density rather than operating speed. The recording density of the storage device used for the storage is approximately 0.6 to 6.0 Gbit/mm².

The information processing device of one embodiment of the present invention operates fast and can retain data for a long period. The storage device included in the information processing device of one embodiment of the present invention can be favorably used as a storage device in a boundary region 901 that includes both the level where the cache is positioned and the level where the main memory is positioned. The storage device included in the information processing device of one embodiment of the present invention can be favorably used as a storage device in a boundary region 902 that includes both the level where the main memory is positioned and the level where the storage is positioned.

The storage device included in the information processing device of one embodiment of the present invention can be favorably used at both the level where the main memory is positioned and the level where the storage is positioned. The storage device included in the information processing device of one embodiment of the present invention can be favorably used at the level where the cache is positioned. FIG. 8B illustrates the hierarchy of various information processing devices different from that in FIG. 8A.

FIG. 8B shows, sequentially from the top level, a memory included as a register in an arithmetic processing device such as a CPU, an SRAM used as a cache, and a 3D OS NAND. The storage device included in the information processing device of one embodiment of the present invention can be used for the cache, the main memory, and the storage. When a high-speed memory of 1 GHz or higher is required as the cache, the cache is included in an arithmetic processing device such as a CPU.

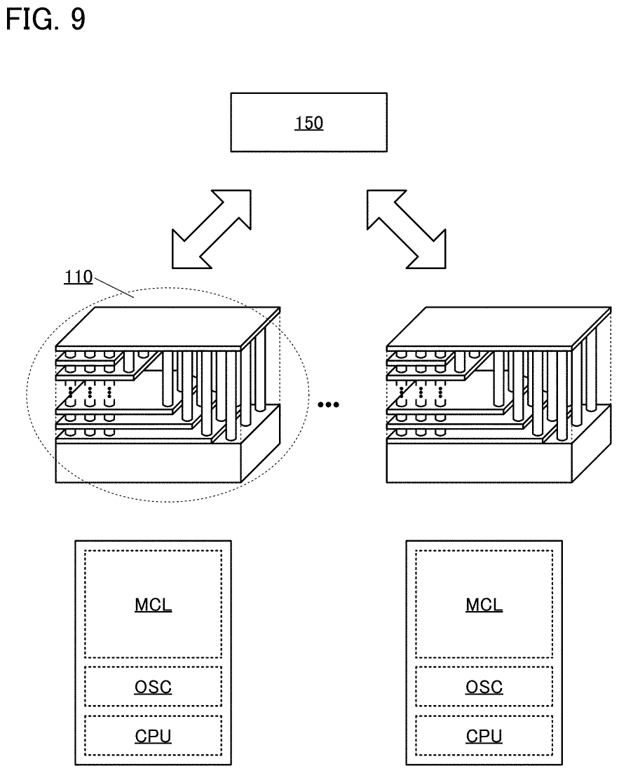

An information processing device 110 of one embodiment of the present invention includes the circuit CPU, the circuit OSC, and the memory cell portion MCL that is a 3D OS NAND having a function of a cache memory, as shown in FIG. 9. A plurality of information processing devices 110 can be managed by a host 150 as shown in FIG. 9. Each of the information processing devices 110 has an arithmetic processing function, and can parallelize writing and reading to and from the NAND universal memory and the cache memory. That is, when the host 150 manages the plurality of information processing devices 110 as shown in FIG. 9, an information processing device enabling non-von Neumann computing can be constructed.

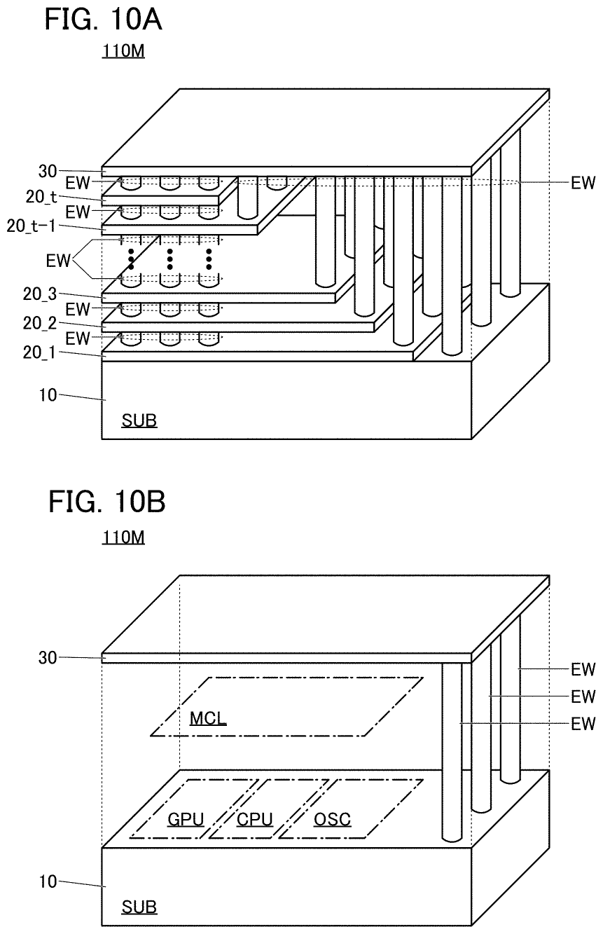

FIG. 10A is a schematic perspective view showing a structure example of an information processing device 110M of one embodiment of the present invention. The information processing device 110M includes the layer 10, the layer 20_1 to the layer 20_t (t is an integer greater than or equal to 2), the layer 30, and the wirings EW.

The structures of the layer 10, the layer 20_1 to the layer 20_t, the layer 30, and the wiring EW are those in FIG. 1A, and thus detailed description thereof is omitted.

The layer 10 and the layer 20_1 to the layer 20_t are provided with circuits that can function by utilizing semiconductor characteristics. The layer 10 is provided with the circuit OSC, the circuit CPU, and a circuit GPU. The layer 20_1 to the layer 20_t are provided with the memory cell portion MCL. The layer 30 is a wiring layer where wirings are formed. The circuit OSC, the circuit CPU, and the circuit GPU in the layer 10 correspond to an arithmetic device.

FIG. 10B is a schematic perspective view in which the layer 20_1 to the layer 20_t and the wirings EW connected to the layers 20 are omitted from FIG. 10A and which illustrates the positional relationships between the circuit OSC, the circuit CPU, the circuit GPU, and the memory cell portion MCL.

The structures of the circuit OSC, the circuit CPU, and the memory cell portion MCL are similar to those in Embodiment 1, and thus detailed description thereof is omitted.

The circuit GPU has a function of performing arithmetic processing of data written to the memory cell portion MCL or data read from the memory cell portion MCL. The arithmetic processing of the data is performed by an arithmetic circuit and the like included in the circuit GPU. The circuit GPU is a circuit mainly for performing product-sum operation processing. By including the GPU, the information processing device 110M can perform efficient inference processing based on an artificial neural network. The circuit GPU is also referred to as an accelerator.

Such inference processing based on an artificial neural network is preferably an arithmetic operation using data that is optimized to have the number of bits less than or equal to 32 bits, preferably less than or equal to 16 bits, further preferably less than or equal to 8 bits, instead of an arithmetic operation using data having a large number of bits, e.g., 64 bits, in which case the power consumption can be reduced without a reduction in arithmetic operation accuracy.

The circuit GPU is formed using transistors formed on the substrate SUB like the circuit OSC and the circuit CPU.

Like the circuit OSC and the circuit CPU, the circuit GPU and the memory cell portion MCL are electrically connected to each other through the wirings EW and the layer 30. The wiring EW has a function of electrically connecting the circuit GPU and the layer 30, and a function of electrically connecting the memory cells included in the memory cell portion MCL and the layer 30.

The circuit GPU is electrically connected to the circuit OSC and the circuit CPU with the use of a wiring formed on the substrate SUB. The data transfer distance between the circuit GPU and the memory cell portion MCL in the information processing device 110M is short, allowing the information processing device 110M to have features such as least signal transmission delay, a resultant high-speed operation, and a minimized increase in power consumption due to parasitic capacitance or the like. The memory cell portion MCL is provided to overlap with and to be above the circuit GPU, thereby inhibiting an increase in the circuit area of the information processing device 110M.

Since it is possible to inhibit an increase in the circuit area of the information processing device 110M, the number of circuits GPU provided can be increased. The number of circuits performing an arithmetic operation in the circuit GPU (the number of cores) can be increased; thus, the frequency of a signal for driving the circuit GPU can be lowered. In addition, the power supply voltage for driving the circuit GPU can be low. As a result, the power consumption required for an arithmetic operation can be reduced to one several tenth, for example.

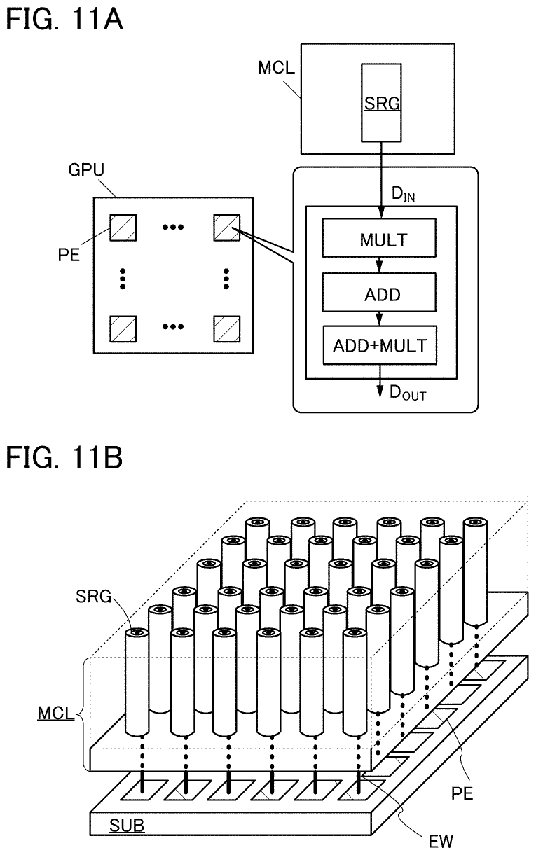

Next, a structure example of the circuit GPU is described. FIG. 11A is a block diagram for illustrating a structure example of the circuit GPU.

The circuit GPU includes a plurality of arithmetic circuits PE for performing an arithmetic operation. The arithmetic circuit PE preferably includes a circuit dedicated for product-sum operation processing as described above. This circuit configuration allows the plurality of arithmetic circuits PE, each of which includes a multiplier circuit MULT, an adder circuit ADD, a product-sum operation circuit ADD+MULT, and other circuits, to process input data D_{IN} in parallel. Each of the circuits included in the arithmetic circuit PE can be formed using a Si transistor. The input data D_{IN} is stored in the strings SRG of the memory cell portion MCL. Each string SRG can be connected to any one of the plurality of arithmetic circuits PE through the wiring EW. Output data D_{OUT}, which is obtained through product-sum operation processing, is output to the circuit CPU or the memory cell portion MCL.

FIG. 11B is a schematic perspective view for illustrating the positional relationship between the strings SRG of the memory cell portion MCL and the plurality of arithmetic circuits PE. The plurality of arithmetic circuits PE provided on the substrate SUB can be provided to overlap with the strings SRG of the memory cell portion MCL with the wirings EW provided therebetween.

A product-sum operation in inference processing necessitates a large quantity of data, for which an extremely large bandwidth (data transfer rate) is needed. Such a large bandwidth can be secured by arranging the strings SRG of the memory cell portion MCL over the arithmetic circuits PE as in the structure of FIG. 11B. Moreover, the distance between circuits can be shortened, and the transfer rate for multiple pieces of data can be accordingly increased. Thus, the power consumption required for a product-sum operation in inference processing can be reduced to one several tenth, for example.

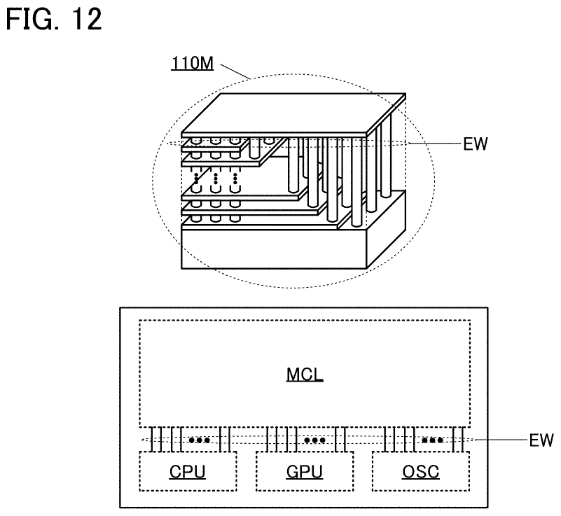

In the information processing device 110M of one embodiment of the present invention, the strings SRG of the memory cell portion MCL can be arranged over the circuit CPU and the circuit OSC as well as over the circuit GPU. Thus, a large bandwidth can be secured for not only the circuit GPU but also the circuit CPU and the circuit OSC as shown in the schematic perspective view and block diagram in FIG. 12.

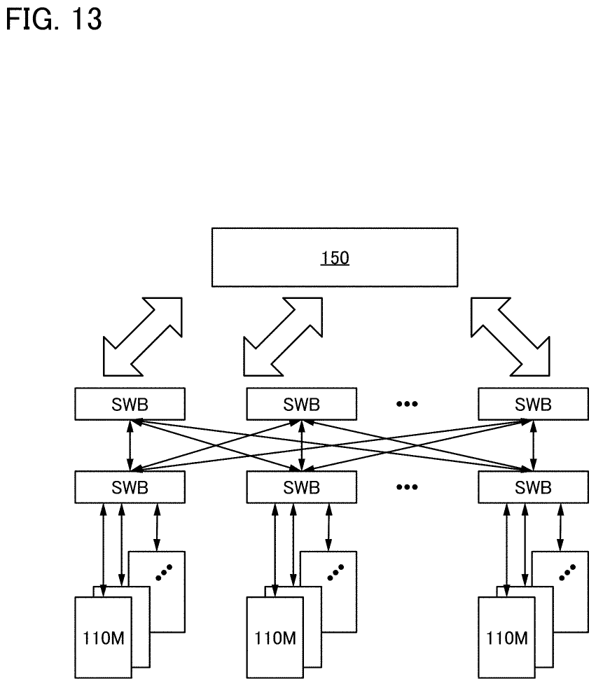

When a plurality of information processing devices 110M of one embodiment of the present invention as described above are combined, they can be used for a data center, a supercomputer, or the like that can be managed by the host 150, as shown in FIG. 13. The information processing devices 110M are electrically connected to switchboards SWB. The information processing devices 110M can be switched with the switchboards SWB. As shown in FIG. 13, each of the plurality of information processing devices 110M can parallelize data writing and data reading. This enables obtaining a supercomputer with reduced power consumption and an increased computation speed.

As shown in FIG. 13, the circuit area in the circuit GPU can be reduced in the information processing device 110M. Specifically, the number of information processing devices 110M serving as computing nodes can be reduced. Thus, the power consumption required for transmission and reception of data can be reduced to one several tenth, for example.

The power consumption in existing data centers or existing supercomputers can be reduced to one thousandth, for example, when optimization of a computer architecture, software, or a driving method is combined with the above-described reduction in power consumption in an arithmetic operation, the above-described reduction in power consumption due to an arithmetic operation dedicated for the product-sum operation during the inference processing, and the above-described reduction in power consumption due to a reduction in the circuit area.

Note that this embodiment can be implemented in appropriate combination with the other embodiments described in this specification.

### Embodiment 2

In this embodiment, structure examples of an information processing device of one embodiment of the present invention will be described.

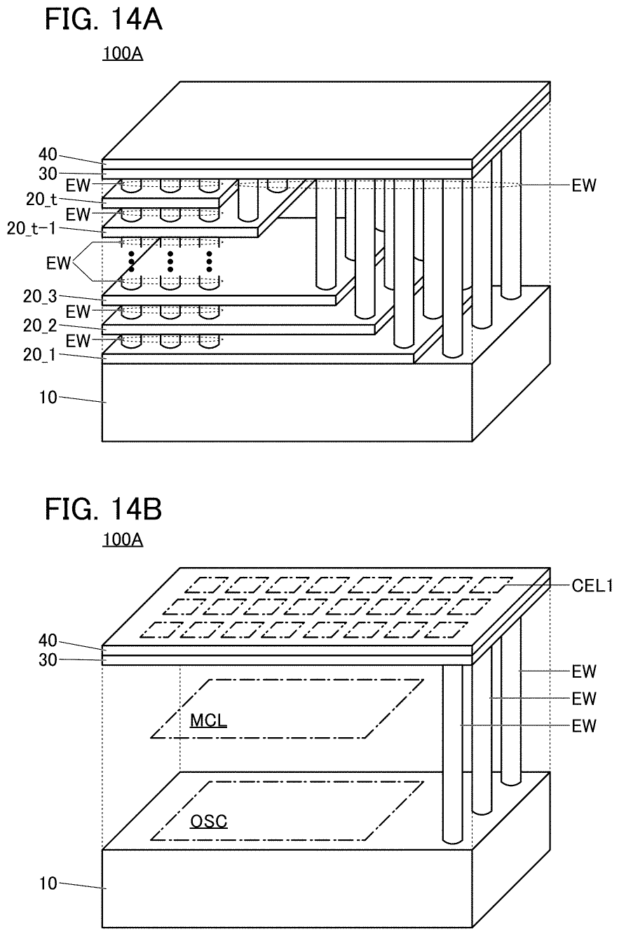

FIG. 14A is a schematic perspective view showing a structure example of an information processing device 100A of one embodiment of the present invention. The information processing device 100A includes the layer 10, the layer 20_1 to the layer 20_t (t is an integer greater than or equal to 2), the layer 30, a layer 40, and the wirings EW.

As illustrated in FIG. 14A, the information processing device 100A has a structure in which the layer 20_1 is stacked above the layer 10, the layer 20_k+1 is stacked above the layer 20_k (k is an integer greater than or equal to 1 and less than or equal to t−1), the layer 30 is stacked above the layer 20_t, and the layer 40 is stacked above the layer 30.

The structures of the layer 10, the layer 20_1 to the layer 20_t, the layer 30, and the wiring EW are similar to those in Embodiment 1, and thus detailed description thereof is omitted.

The layer 40 of the information processing device 100A includes a plurality of electrodes for electrical connection to the circuit CPU that is separately formed. These electrodes can be used as micro-bumps formed using copper or aluminum. By the use of the electrodes for connection between metal electrodes, the information processing device 100A can be bonded to a substrate that includes the circuit CPU provided with electrodes.

The layer 10 and the layer 20_1 to the layer 20_t are each provided with a circuit that can function by utilizing semiconductor characteristics. The layer 10 is provided with the circuit OSC. The layer 20_1 to the layer 20_t are provided with the memory cell portion MCL. The layer 30 is a wiring layer where wirings are formed.

FIG. 14B is a schematic perspective view in which the layer 20_1 to the layer 20_t and the wirings EW connected to the layers 20 are omitted from FIG. 14A and which illustrates the positional relationships between the circuit OSC, the memory cell portion MCL, and the layer 40 provided with a plurality of electrodes CEL1.

The structures of the circuit OSC and the memory cell portion MCL are similar to those in Embodiment 1, and thus detailed description thereof is omitted.

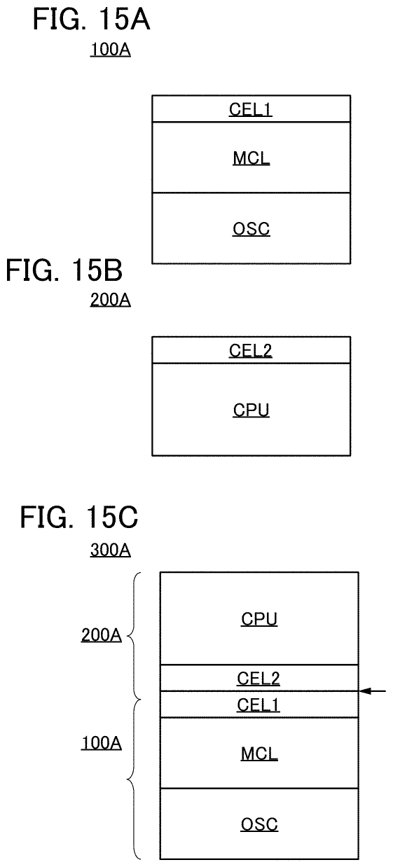

Next, a structure example of the information processing device 100A including the electrode CEL1 is described. FIG. 15A is a block diagram showing the structure example of the information processing device 100A.

In the block diagram of FIG. 15A, the information processing device 100A includes the electrode CEL1, the circuit OSC, and the memory cell portion MCL. As described in Embodiment 1, the circuit OSC has a function of performing arithmetic processing of data written to the memory cell portion MCL or data read from the memory cell portion MCL. The electrode CEL1 is an electrode for extracting the data written to or read from the memory cell portion MCL.

FIG. 15B illustrates a structure example of an information processing device 200A including the circuit CPU. FIG. 15B is a block diagram showing the structure example of the information processing device 200A.

In the block diagram of FIG. 15B, the information processing device 200A includes an electrode CEL2 and the circuit CPU (also referred to as a central processing device). As described in Embodiment 1, the circuit CPU has a function of performing arithmetic processing when supplied with, through the electrode CEL2, data written to the memory cell portion MCL or data read from the memory cell portion MCL. The electrode CEL2 is an electrode for extracting data through the electrode CEL1 of the information processing device 100A.

The information processing device 100A of this embodiment shown in FIG. 15A is used in combination with the information processing device 200A shown in FIG. 15B. Specifically, the electrode CEL1 is bonded to the electrode CEL2 (the position indicated by the arrow in FIG. 15C) to form an information processing device 300A having reduced power consumption as shown in FIG. 15C.

Note that this embodiment can be implemented in appropriate combination with the other embodiments described in this specification.

### Embodiment 3

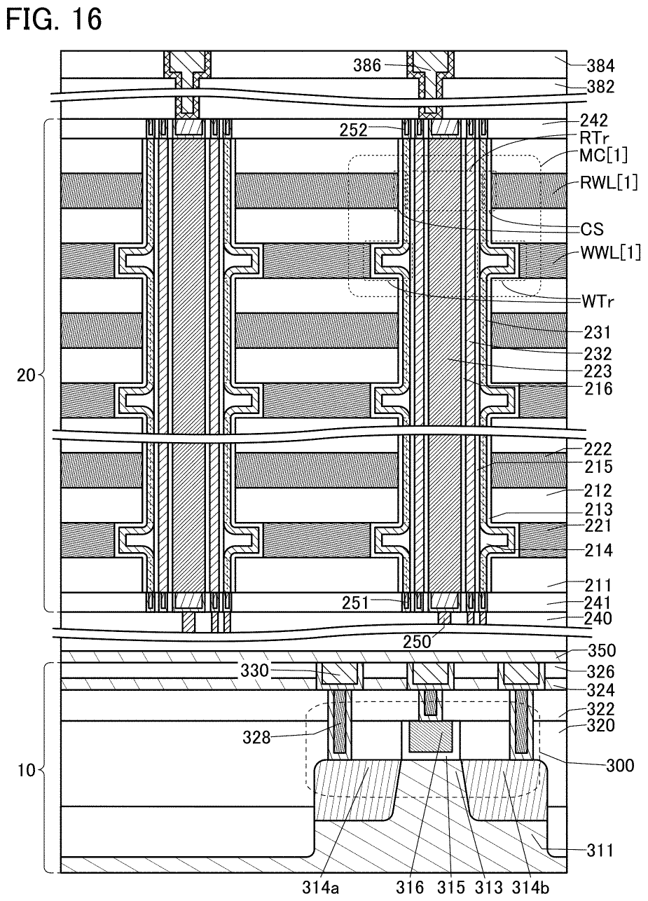

In this embodiment, a structure example of a transistor included in the information processing device 100 described in the above embodiment will be described. FIG. 16 shows a cross-sectional structure example of the layer 10 and the layer 20. In the structure example in this embodiment, a single crystal silicon substrate is used as the substrate SUB, and the layer 20 is a 3D OS NAND.

In the layer 10 shown in FIG. 16, a transistor 300 is provided on a substrate 311 and includes a conductor 316, an insulator 315, a semiconductor region 313 that is a part of the substrate 311, and a low-resistance region 314a and a low-resistance region 314b functioning as a source region and a drain region.

In the transistor 300, the top surface and the side surface in the channel width direction of the semiconductor region 313 are covered with the conductor 316 with the insulator 315 therebetween. Such a Fin-type transistor 300 can have an increased effective channel width, and thus the transistor 300 can have improved on-state characteristics. In addition, since contribution of an electric field of a gate electrode can be increased, the off-state characteristics of the transistor 300 can be improved.

Note that the transistor 300 can be either a p-channel transistor or an n-channel transistor.

It is preferable that a region of the semiconductor region 313 where a channel is formed, a region in the vicinity thereof, the low-resistance region 314a and the low-resistance region 314b functioning as the source region and the drain region, and the like contain a semiconductor such as a silicon-based semiconductor, further preferably single crystal silicon. Alternatively, these regions may be formed using a material containing Ge (germanium), SiGe (silicon germanium), GaAs (gallium arsenide), GaN (gallium nitride), GaAlAs (gallium aluminum arsenide), or the like. A structure using silicon whose effective mass is controlled by applying stress to the crystal lattice and changing the lattice spacing may be employed. Alternatively, the transistor 300 may be an HEMT (High Electron Mobility Transistor) with GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

The conductor 316 functioning as a gate electrode can be formed using a semiconductor material such as silicon containing an element that imparts n-type conductivity, such as arsenic or phosphorus, or an element that imparts p-type conductivity, such as boron, or using a conductive material such as a metal material, an alloy material, or a metal oxide material.

Note that since the work function of a conductor depends on a material of the conductor, Vth of the transistor can be adjusted by changing the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

Note that the transistor 300 shown in FIG. 16 is an example and is not limited to the structure shown therein; an appropriate transistor is used in accordance with a circuit configuration or a driving method.

An insulator 320, an insulator 322, an insulator 324, and an insulator 326 are stacked in this order to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may have a function of a planarization film for planarizing a level difference caused by the transistor 300 or the like provided below the insulator 322. For example, the top surface of the insulator 322 may be planarized by planarization treatment using a chemical mechanical polishing (CMP) method or the like to improve planarity.

The insulator 324 is preferably formed using a film with a barrier property that prevents diffusion of hydrogen and/or impurities from the substrate 311, the transistor 300, or the like into the layer 20.

For the film having a barrier property against hydrogen, silicon nitride formed by a CVD method can be used, for example. Here, diffusion of hydrogen to a semiconductor element including an oxide semiconductor in the layer 20 degrades the characteristics of the semiconductor element in some cases. Therefore, a film that inhibits hydrogen diffusion is preferably used between the layer 20 and the layer 10. The film that inhibits hydrogen diffusion is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. When a material with a low relative permittivity is used for an interlayer film, the parasitic capacitance generated between wirings can be reduced.

A conductor 328, a conductor 330, and the like are embedded in the insulator 320, the insulator 322, the insulator 324, and the insulator 326. Note that the conductor 328 and the conductor 330 each have a function of a plug or a wiring. A plurality of conductors functioning as plugs or wirings are collectively denoted by the same reference numeral in some cases. Moreover, in this specification and the like, a wiring and a plug connected to the wiring may be a single component. That is, there are cases where a part of a conductor functions as a wiring and another part of the conductor functions as a plug.

As a material for each of plugs and wirings (the conductor 328, the conductor 330, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

Although not illustrated in FIG. 16, a wiring layer may be provided over the insulator 326 and the conductor 330. For example, it is preferable that an insulator having a barrier property against hydrogen like the insulator 324 be provided over the insulator 326 and the conductor 330 and a conductor having a barrier property against hydrogen be formed in the insulator. When the conductor having a barrier property against hydrogen is formed in an opening portion of the insulator having a barrier property against hydrogen, the layer 20 and the layer 10 can be separated from each other by the barrier layer, and hydrogen diffusion into the layer 10 from the layer 20 can be inhibited.

Note that for the conductor having a barrier property against hydrogen, tantalum nitride is preferably used, for example. In addition, the use of a stack including tantalum nitride and tungsten, which has high conductivity, can inhibit diffusion of hydrogen from the transistor 300 while the conductivity of a wiring is maintained. In that case, a structure is preferable in which a tantalum nitride layer having a barrier property against hydrogen is in contact with the insulator having a barrier property against hydrogen. Note that in FIG. 16, an insulator 350 having a barrier property against hydrogen is provided over the insulator 326 and the conductor 330.

In the layer 20 illustrated in FIG. 16, the storage element included in the three-dimensional NAND memory element includes a transistor RTr, a transistor WTr, and a capacitor CS, for example.

The layer 20 shown in FIG. 16 is provided above the layer 10. The layer 20 includes an insulator 211 to an insulator 215, an insulator 240 to an insulator 242, a conductor 221, a conductor 222, a conductor 250 to a conductor 252, a semiconductor 231, and a semiconductor 232 above the layer 10.

The insulator 240 is provided above the layer 10. Thus, the insulator 350 positioned under the insulator 240 is preferably formed by a deposition method with good planarity. The insulator 350 is preferably subjected to CMP treatment.

For the insulator 240, a material containing silicon oxide or silicon oxynitride can be used, for example. For example, it is possible to use a single layer or a stacked layer of an insulator including a material selected from boron, carbon, nitrogen, oxygen, fluorine, magnesium, aluminum, silicon, phosphorus, chlorine, argon, gallium, germanium, yttrium, zirconium, lanthanum, neodymium, hafnium, tantalum, and the like.

An insulator 241 is stacked over the insulator 240. Any of the materials that can be used for the insulator 240 can be used as the insulator 241, for example.

The conductor 250 is embedded in the insulator 240, and the conductor 251 is embedded in the insulator 241. The conductor 250 and the conductor 251 each have a function of a plug or a wiring. Furthermore, a plurality of conductors functioning as plugs or wirings illustrated in FIG. 16 are collectively denoted by the same reference numeral in some cases. Moreover, in this specification and the like, a wiring and a plug connected to the wiring may be a single component. That is, there are cases where a part of a conductor functions as a wiring and another part of the conductor functions as a plug.

For the conductor 250 and the conductor 251, any of the materials that can be used for the conductor 328 and the conductor 330 can be used, for example.

The insulator 211 is provided over the insulator 241. The conductor 221 is provided over the insulator 211. The insulator 212 is provided over the conductor 221. In addition, the conductor 222 is provided over the insulator 212. That is, the insulator 211, the conductor 221, the insulator 212, and the conductor 222 are stacked in this order (they are referred to as a stacked body). The layer 20 illustrated in FIG. 16 includes as many stacked bodies as the storage elements included in one string.

In the manufacturing process of the transistor included in the information processing device in FIG. 16, an opening portion is provided in the insulator 211, the conductor 221, the insulator 212, and the conductor 222 through formation of a resist mask, etching treatment, or the like. At this time, the conductor 221 is selectively removed, and a depression portion is formed by the insulator 211, the conductor 221, and the insulator 212. In this case, the conductor 221 is preferably formed using a material having a higher etching rate than the insulator 211, the insulator 212, and the conductor 222.

The formation of the resist mask can be performed, for example, by a lithography method, a printing method, an inkjet method, or the like as appropriate. Formation of the resist mask by an inkjet method needs no photomask; thus, fabrication cost can be reduced. For the etching treatment, either a dry etching method or a wet etching method or both of them may be used.

The insulator 213, the semiconductor 231, the insulator 214, the insulator 215, the semiconductor 232, the insulator 216, and the conductor 223 are formed in this order in the opening portion formed by the etching treatment.

A film with a barrier property which prevents diffusion of hydrogen and/or impurities is preferably used as the insulator 211 and the insulator 212, for example. Thus, the insulator 211 and the insulator 212 can be formed using, for example, a material similar to that of the insulator 240.

For the conductor 221 and the conductor 222, for example, the material that can be used for the conductor 251 is preferably used. In particular, a conductive material having a function of inhibiting transmission of an impurity such as water or hydrogen is preferably used for the conductor 221 and the conductor 222.

The insulator 213 and the semiconductor 231 are formed in this order on the side surface of the above-described opening portion formed by the etching treatment. The insulator 214 is formed to fill the depression portion of the opening portion.

As a formation method of the insulator 214, for example, the insulator 214 is formed on the side surface of the opening portion such that the depression portion of the opening portion is filled, and then, part of the insulator 214 is removed by etching treatment so that the insulator 214 remains in the depression portion and the semiconductor 231 is exposed.

For the insulator 213, silicon oxide or silicon oxynitride can be used, for example. Alternatively, for the insulator 213, aluminum oxide, hafnium oxide, or an oxide containing aluminum and hafnium can be used, for example. The insulator 213 may be an insulator including a stack of any of the above.

A metal oxide is preferably used as the semiconductor 231. For example, as the semiconductor 231, a metal oxide such as an In-M-Zn oxide (the element M is one or more kinds selected from aluminum, gallium, yttrium, copper, vanadium, beryllium, boron, tin, titanium, iron, nickel, germanium, zirconium, molybdenum, lanthanum, cerium, neodymium, hafnium, tantalum, tungsten, magnesium, and the like) is preferably used. As the semiconductor 231, In—Ga oxide or In—Zn oxide can be used. A metal oxide is used as the semiconductor 231 hereinafter in this embodiment.

When the formed semiconductor 231 is subjected to heat treatment in an oxygen atmosphere before formation of the insulator 214, oxygen can be supplied to the metal oxide of the semiconductor 231. Then, treatment for supplying an impurity or the like to the metal oxide of the semiconductor 231 is performed after the formation of the insulator 214, whereby a region of the semiconductor 231, which is exposed to the opening portion, can have reduced resistance. That is, a region of the semiconductor 231 in contact with the insulator 214 becomes a high-resistance region, and a region of the semiconductor 231 not in contact with the insulator 214 becomes a low-resistance region.

As the treatment for supplying an impurity or the like to the metal oxide of the semiconductor 231, for example, the following can be given: formation of a conductor on the side surface of the opening portion and removal of the conductor after the insulator 214 fills the depression portion of the opening portion. When the conductive film is in contact with the metal oxide of the semiconductor 231, a metal element contained in the conductive film is diffused into the semiconductor 231 to form a metal compound with a constitute element of the semiconductor 231 in some cases. The metal compound forms the low-resistance region in the semiconductor 231.

It is preferable that the insulator 214 not include a component forming a compound with a component included in the semiconductor 231 at the interface with the semiconductor 231 that has already been formed and in the vicinity of the interface. Specifically, silicon oxide or the like can be used for the insulator 214, for example.

After that, the insulator 215, the semiconductor 232, the insulator 216, and the conductor 223 are formed in this order over the formation surface of the insulator 213 and the insulator 214. By the formation of the conductor 223, the opening portion provided in the stacked body is filled.

For the insulator 215 and the insulator 216, the material that can be used for the insulator 213 is preferably used, for example.

Like the semiconductor 231, the semiconductor 232 is preferably formed using a metal oxide described in Embodiment 5, for example. In particular, a CAAC-OS to be described later is suitable as the metal oxide. For example, in the case where polycrystalline silicon is used for the semiconductor 231 and the semiconductor 232, the electron trap density might increase due to a crystal grain boundary that might be formed in the polycrystalline silicon and the transistor characteristics might greatly vary. Meanwhile, no clear crystal grain boundary is observed in a CAAC-OS, and thus variation in the transistor characteristics can be suppressed.

The material that can be used for the conductor 251 is preferably used for the conductor 223, for example. In particular, a conductive material having a function of inhibiting transmission of an impurity such as water or hydrogen is preferably used for the conductor 223.

The insulator 242 is provided in the upper portion of the formed string. The material that can be used for the insulator 240 can be used for the insulator 242, for example.

The conductor 252 is embedded in the insulator 242. The conductor 252 has a function of a plug or a wiring. For the conductor 252, any of the materials that can be used for the conductor 328 and the conductor 330 can be used, for example. Furthermore, a conductor 386 is embedded in an insulator 382 and an insulator 384. As each of the insulator 382 and the insulator 384, any of materials that can be used as the insulator 240 can be used, for example. The conductor 386 has a function of a plug or a wiring. For the conductor 386, any of the materials that can be used for the conductor 328 and the conductor 330 can be used, for example.

Note that the wiring WL illustrated in FIG. 2 corresponds to the conductor 221 and the conductor 222; the conductor 221 is used in data writing, and the conductor 222 is used in data reading.

Accordingly, the capacitor CS is formed in which the conductor 222 serves as one electrode, a region of the insulator 213 in contact with the conductor 222 serves as a dielectric, and a region of the semiconductor 231 overlapping with the conductor 222 serves as the other electrode. In addition, the transistor RTr is formed in which a region of the semiconductor 231 overlapping with the conductor 222 serves as a gate, a region of the insulator 215 overlapping with the conductor 222 serves as a gate insulating film, a region of the semiconductor 232 overlapping with the conductor 222 serves as a channel formation region, a region of the insulator 216 overlapping with the conductor 222 serves as a gate insulating film, and a region of the conductor 223 overlapping with the conductor 222 serves as a back gate. Furthermore, the transistor WTr is formed in which the conductor 221 serves as a gate, the insulator 213 overlapping with the conductor 221 serves as a gate insulating film, and a region of the semiconductor 231 overlapping with the conductor 221 serves as a channel formation region.

Note that the insulators, the conductors, the semiconductors, and the like disclosed in this specification and the like can be formed by a PVD (Physical Vapor Deposition) method or a CVD (Chemical Vapor Deposition) method. Examples of a PVD method include a sputtering method, a resistance heating evaporation method, an electron beam evaporation method, and a PLD (Pulsed Laser Deposition) method. Examples of the CVD method include a plasma CVD method and a thermal CVD method. In particular, examples of a thermal CVD method include a MOCVD (Metal Organic Chemical Vepor Deposition) method and an ALD (Atomic Layer Deposition) method.

A thermal CVD method, which is a deposition method not using plasma, has an advantage that no defect due to plasma damage is generated. Deposition by a thermal CVD method may be performed in such a manner that a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of a plurality of kinds of source gases, an inert gas (argon, nitrogen, or the like) or the like is introduced at the same time as or after the introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on a surface of the substrate to form a first thin layer; then, the second source gas is introduced to react with the first thin layer; as a result, a second thin layer is stacked over the first thin layer, so that a thin film is formed. The sequence of the gas introduction is controlled and repeated a plurality of times until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a film thickness and is thus suitable for manufacturing a minute FET.

A variety of films such as the metal film, the semiconductor film, and the inorganic insulating film disclosed in the above-described embodiments can be formed by a thermal CVD method such as an MOCVD method or an ALD method; for example, in the case of forming an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus using ALD, two kinds of gases, ozone (03) as an oxidizer and a source gas which is obtained by vaporizing liquid containing a solvent and a hafnium precursor compound (hafnium alkoxide or hafnium amide such as tetrakis(dimethylamide)hafnium (TDMAH, Hf[N(CH₃)₂]₄)), are used. Furthermore, examples of another material include tetrakis(ethylmethylamide)hafnium.

For example, in the case where an aluminum oxide film is formed with a deposition apparatus using ALD, two kinds of gases, H₂O as an oxidizer and a source gas which is obtained by vaporizing liquid containing a solvent and an aluminum precursor compound (trimethylaluminum (TMA, Al(CH₃)₃) or the like) are used. Furthermore, examples of another material include tris(dimethylamide)aluminum, triisobutylaluminum, and aluminum tris(2,2,6,6-tetramethyl-3,5-heptanedionate).

For example, in the case where a silicon oxide film is formed with a deposition apparatus using ALD, hexachlorodisilane is adsorbed on a surface on which a film is to be formed, and radicals of an oxidizing gas (O₂ or dinitrogen monoxide) are supplied to react with the adsorbate.

For example, in the case where a tungsten film is deposited with a deposition apparatus using ALD, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

For example, in the case where an oxide semiconductor film, for example, an In—Ga—Zn—O film, is deposited with a deposition apparatus using ALD, an In(CH₃)₃ gas and an O₃ gas) are sequentially and repeatedly introduced to form an In—O layer, a Ga(CH₃)₃ gas and an O₃ gas) are sequentially and repeatedly introduced to form a GaO layer, and then a Zn(CH₃)₂ gas and an O₃ gas) are sequentially and repeatedly introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas such as Ar may be used instead of an O₃ gas), it is preferable to use an O₃ gas) which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, a Zn(CH₃)₂ gas may be used. Note that although the above description is made on the deposition apparatus using ALD, which is an example of a thermal CVD method, the present invention is not limited thereto. A deposition apparatus using ALD involving plasma (PEALD: Plasma Enhanced ALD) may be employed.

With the use of this structure, a change in electrical characteristics can be inhibited and reliability can be improved in an information processing device including an OS transistor. Alternatively, an OS transistor having a high on-state current can be provided. Alternatively, an OS transistor having a low off-state current can be provided. Alternatively, an information processing device including an OS transistor can be miniaturized or highly integrated.

Note that this embodiment can be implemented in appropriate combination with the other embodiments described in this specification.

### Embodiment 4

This embodiment describes an example of an operation in the case where the circuit GPU (hereinafter also referred to as a GPU or an accelerator) executes part of an arithmetic operation of a program executed by the circuit CPU (hereinafter also referred to as a CPU) described in the above embodiment.

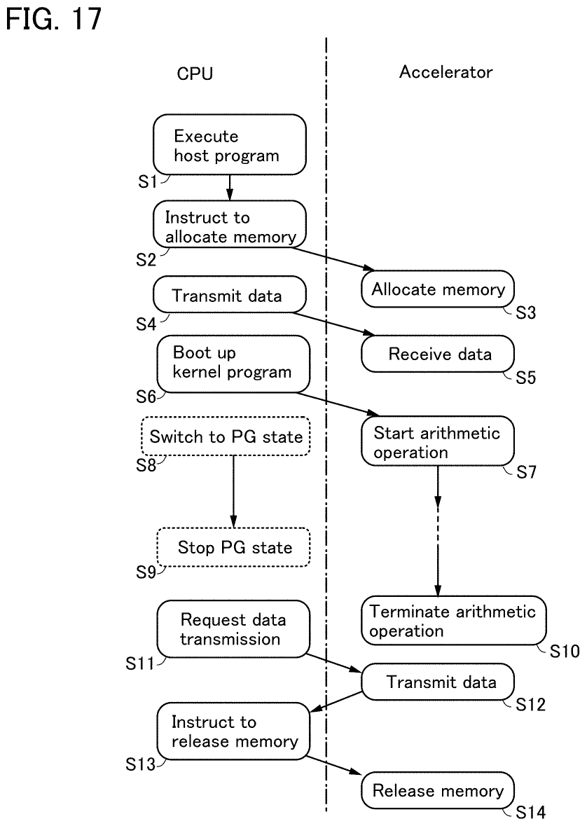

FIG. 17 shows an operation example of the case where the accelerator executes part of an arithmetic operation of a program executed by the CPU.

The CPU executes a host program (Step S1).

In the case where the CPU confirms an instruction to allocate, to a memory portion, a region for data needed in performing an arithmetic operation using the accelerator (Step S2), the CPU allocates the region for the data to the memory portion (Step S3).

Next, the CPU transmits input data from a main memory to the above-described memory portion (Step S4). The above-described memory portion receives the input data and stores the input data in the region allocated in Step S2 (Step S5).

In the case where the CPU confirms an instruction to boot up the kernel program (Step S6), the accelerator starts execution of the kernel program (Step S7).

Immediately after the accelerator starts the execution of the kernel program, the CPU may be switched from the state of performing an arithmetic operation to a PG (power gating) state (Step S8). In that case, just before the accelerator terminates the execution of the kernel program, the CPU is switched from the PG state to a state of performing an arithmetic operation (Step S9). By bringing the CPU into the PG state during the period from Step S8 to Step S9, the power consumption and heat generation of a semiconductor device as a whole can be suppressed.

When the accelerator terminates the execution of the kernel program, output data is stored in the above-described memory portion (Step S10).

After the execution of the kernel program is terminated, in the case where the CPU confirms an instruction to transmit the output data stored in the memory portion to the main memory (Step S11), the above-described output data is transmitted to the above-described main memory and stored in the above-described main memory (Step S12).

In the case where the CPU confirms an instruction to release the region for the data allocated to the memory portion (Step S13), the region allocated to the above-described memory portion is released (Step S14).

By repeating the operations from Step S1 to Step S14 described above, part of the arithmetic operation of the program executed by the CPU can be executed by the accelerator while the power consumption and heat generation of the CPU and the accelerator are suppressed.

This embodiment can be combined with the description of the other embodiments as appropriate.

### Embodiment 5

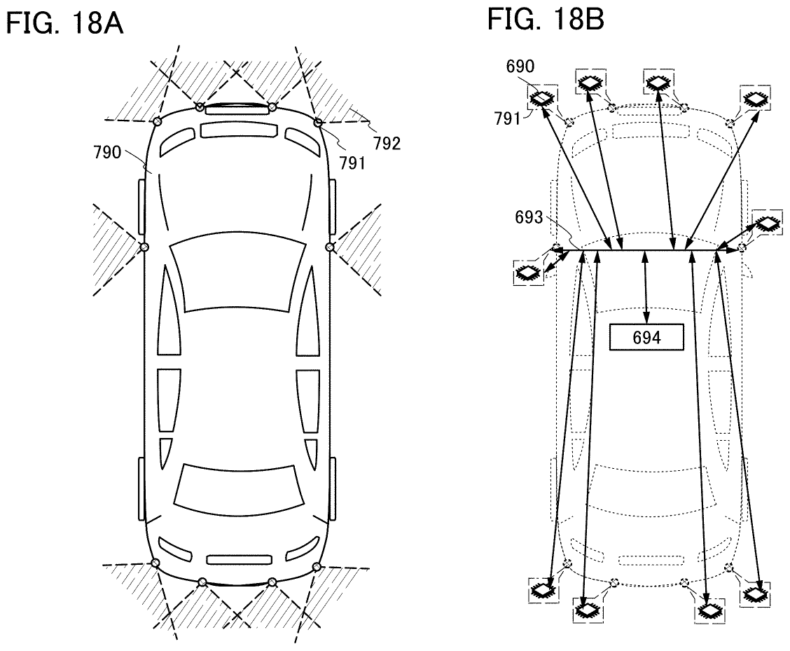

In this embodiment, a moving object in which the information processing device 100 described in the above embodiment can be used will be described with reference to FIG. 18.

FIG. 18A illustrates an external view of an automobile as an example of the moving object. FIG. 18B is a simplified diagram illustrating data transmission in the automobile. An automobile 790 includes a plurality of cameras 791 and the like. The automobile 790 also includes various sensors such as an infrared radar, a millimeter wave radar, and a laser radar (not illustrated) and the like.

In the automobile 790, the camera 791 and the like can include an integrated circuit 690 for which the information processing device 100 described above in Embodiment 1 can be used. The automobile 790 can perform autonomous driving by judging surrounding traffic information such as the presence of a guardrail or a pedestrian in such a manner that the camera 791 processes a plurality of images taken in a plurality of imaging directions 792 with the integrated circuit 690 for which the information processing device 100 described above in Embodiment 1 can be used and the plurality of images are analyzed collectively with a host controller 694 and the like through a bus 693 and the like. The integrated circuit 690 can be used for a system for navigation, risk prediction, or the like.

When arithmetic processing of a neural network or the like is performed on the obtained image data in the integrated circuit 690, for example, processing for the following can be performed: an increase in image resolution, a reduction in image noise, face recognition (for security reasons or the like), object recognition (for autonomous driving or the like), image compression, image compensation (a wide dynamic range), restoration of an image of a lensless image sensor, positioning, character recognition, and a reduction of glare and reflection.

Note that although an automobile is described above as an example of the moving object, the moving object is not limited to an automobile. Other examples of the moving object include a train, a monorail train, a ship, and a flying object (a helicopter, an unmanned aircraft (a drone), an airplane, and a rocket), and these moving objects can include a system utilizing artificial intelligence when equipped with a computer of one embodiment of the present invention.

### Embodiment 6

This embodiment will show examples of a semiconductor wafer where the information processing device or the like described in the above embodiment is formed and electronic components incorporating the information processing device.

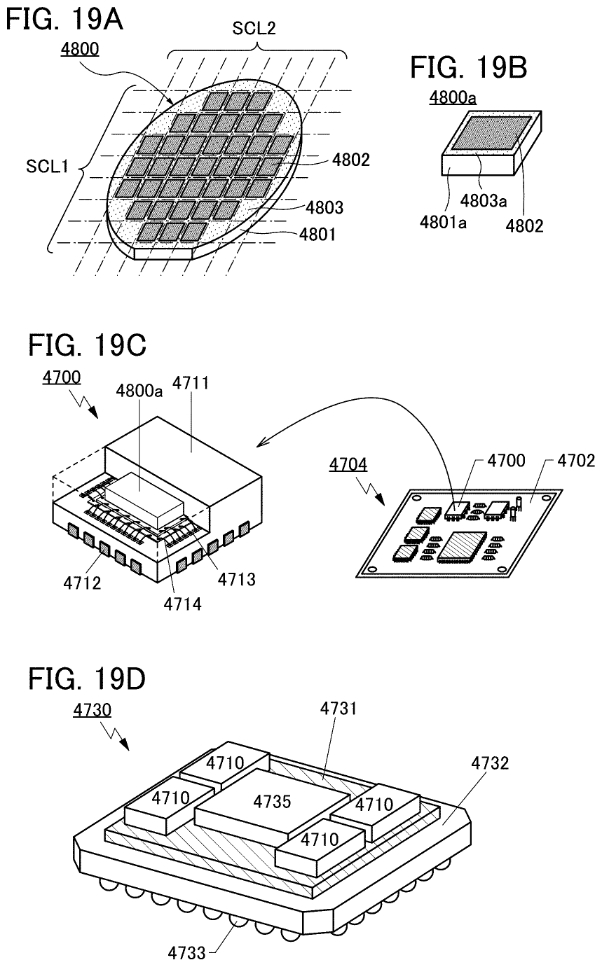

First, an example of a semiconductor wafer where the information processing device or the like is formed is described with reference to FIG. 19A.

A semiconductor wafer 4800 shown in FIG. 19A includes a wafer 4801 and a plurality of circuit portions 4802 provided on the top surface of the wafer 4801. A portion without the circuit portion 4802 on the top surface of the wafer 4801 is a spacing 4803 that is a region for dicing.

The semiconductor wafer 4800 can be fabricated by forming the plurality of circuit portions 4802 on a surface of the wafer 4801 by a pre-process. After that, a surface of the wafer 4801 opposite to the surface provided with the plurality of circuit portions 4802 may be ground to thin the wafer 4801. Through this step, warpage or the like of the wafer 4801 is reduced and the size of the component can be reduced.

A dicing step is performed as the next step. The dicing is performed along scribe lines SCL1 and scribe lines SCL2 (referred to as dicing lines or cutting lines in some cases) indicated by dashed-dotted lines. Note that to perform the dicing step easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing step, a chip 4800a as shown in FIG. 19B can be cut out from the semiconductor wafer 4800. The chip 4800a includes a wafer 4801a, the circuit portion 4802, and a spacing 4803a. Note that it is preferable to make the spacing 4803a as small as possible. In this case, the width of the spacing 4803 between adjacent circuit portions 4802 is substantially the same as a length of a cutting allowance of the scribe line SCL1 or a cutting allowance of the scribe line SCL2.

Note that the shape of an element substrate of one embodiment of the present invention is not limited to the shape of the semiconductor wafer 4800 shown in FIG. 19A. The element substrate may be a rectangular semiconductor wafer, for example. The shape of the element substrate can be changed as appropriate, depending on a manufacturing process of an element and an apparatus for manufacturing the element.

FIG. 19C is a perspective view of an electronic component 4700 and a substrate (a mounting board 4704) on which the electronic component 4700 is mounted. The electronic component 4700 illustrated in FIG. 19C includes the chip 4800a in a mold 4711. As the chip 4800a, the information processing device of one embodiment of the present invention can be used, for example.

To illustrate the inside of the electronic component 4700, some portions are omitted in FIG. 19C. The electronic component 4700 includes a land 4712 outside the mold 4711. The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, whereby the mounting board 4704 is completed.

FIG. 19D shows a perspective view of an electronic component 4730. The electronic component 4730 is an example of a SiP (System in package) or an MCM (Multi Chip Module). In the electronic component 4730, an interposer 4731 is provided over a package substrate 4732 (a printed circuit board), and a semiconductor device 4735 and a plurality of information processing devices 4710 are provided over the interposer 4731.

Examples of the information processing device 4710 include the chip 4800a, the information processing device described in the above embodiment, and a high bandwidth memory (HBM). An integrated circuit such as a CPU, a GPU, an FPGA, or a storage device can be used as the semiconductor device 4735. Note that in this specification and the like, a semiconductor device generally means a device that can function by utilizing semiconductor characteristics.

As the package substrate 4732, a ceramic substrate, a plastic substrate, a glass epoxy substrate, or the like can be used. As the interposer 4731, a silicon interposer, a resin interposer, or the like can be used.

The interposer 4731 includes a plurality of wirings and has a function of electrically connecting a plurality of integrated circuits with different terminal pitches. The plurality of wirings have a single-layer structure or a layered structure. Moreover, the interposer 4731 has a function of electrically connecting an integrated circuit provided over the interposer 4731 to an electrode provided on the package substrate 4732. Accordingly, the interposer is sometimes referred to as a “redistribution substrate” or an “intermediate substrate”. A through electrode is provided in the interposer 4731 and the through electrode is used to electrically connect an integrated circuit and the package substrate 4732 in some cases. In the case of using a silicon interposer, a TSV (Through Silicon Via) can also be used as the through electrode.

A silicon interposer is preferably used as the interposer 4731. The silicon interposer can be manufactured at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided thereon is less likely to occur. It is particularly preferable to use a silicon interposer for a 2.5D package (2.5D mounting) in which a plurality of integrated circuits are arranged side by side on the interposer.

A heat sink (a radiator plate) may be provided to overlap with the electronic component 4730. In the case of providing a heat sink, the heights of integrated circuits provided over the interposer 4731 are preferably equal to each other. For example, in the electronic component 4730 described in this embodiment, the heights of the information processing devices 4710 and the semiconductor device 4735 are preferably equal to each other.

To mount the electronic component 4730 on another substrate, an electrode 4733 may be provided on the bottom portion of the package substrate 4732. FIG. 19D shows an example in which the electrode 4733 is formed of a solder ball. The solder balls are provided in a matrix on the bottom portion of the package substrate 4732, whereby BGA (Ball Grid Array) mounting can be achieved. Alternatively, the electrode 4733 may be formed of a conductive pin. When the conductive pins are provided in a matrix on the bottom portion of the package substrate 4732, PGA (Pin Grid Array) mounting can be achieved.

The electronic component 4730 can be mounted on another substrate by any of various mounting methods other than BGA and PGA. For example, a mounting method such as an SPGA (Staggered Pin Grid Array), an LGA (Land Grid Array), a QFP (Quad Flat Package), a QFJ (Quad Flat J-leaded package), or a QFN (Quad Flat Non-leaded package) can be employed.

Note that this embodiment can be combined with any of the other embodiments in this specification as appropriate.

### Embodiment 7

In this embodiment, application examples of the information processing device of one embodiment of the present invention will be described.

The information processing device of one embodiment of the present invention can be used, for example, as information processing devices of a variety of electronic devices (e.g., information terminals, computers, smartphones, e-book readers, digital still cameras, video cameras, video recording/reproducing devices, navigation systems, and game machines). The information processing device of one embodiment of the present invention can also be used for image sensors, IoT (Internet of Things) terminal devices, healthcare devices, and the like. Here, the computers refer not only to tablet computers, notebook computers, and desktop computers, but also to large computers such as server systems.

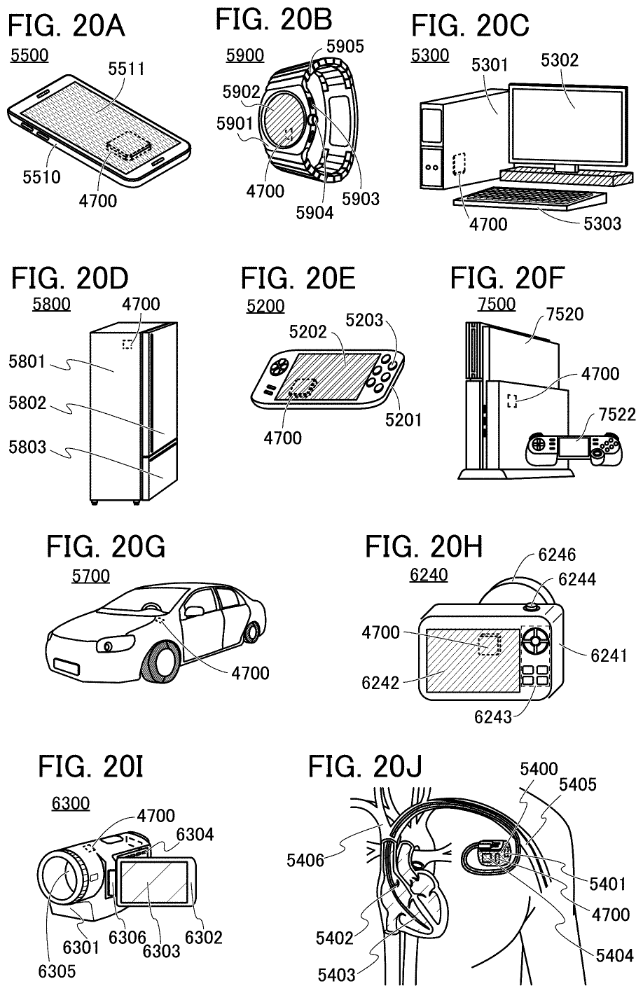

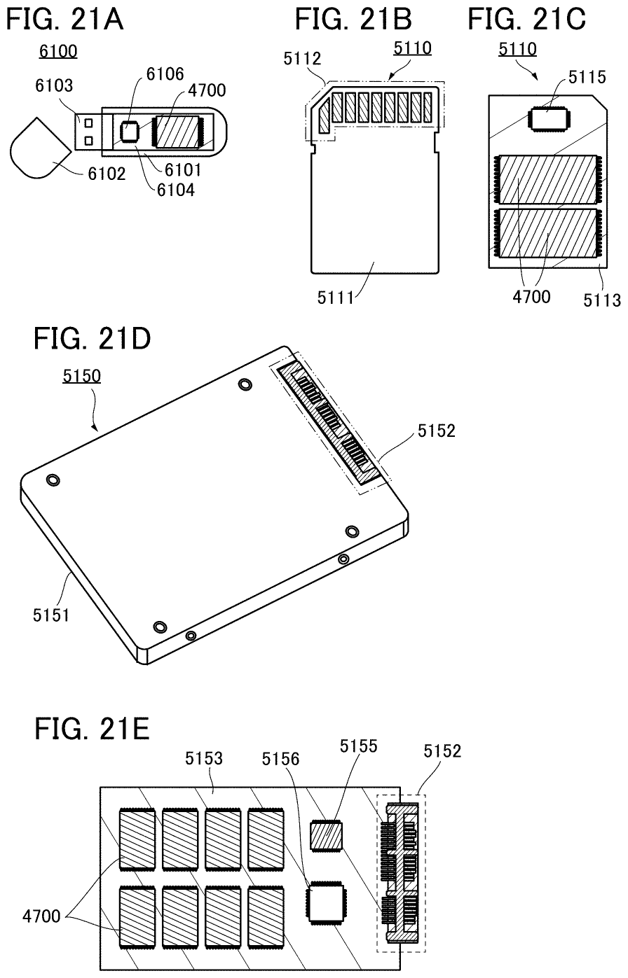

Examples of an electronic device including the storage device of one embodiment of the present invention will be described. FIG. 20A to FIG. 20J and FIG. 21A to FIG. 21E each show that the electronic component 4700 or the electronic component 4730, each of which includes the information processing device, is included in an electronic device.

An information terminal 5500 illustrated in FIG. 20A is a mobile phone (a smartphone), which is a type of information terminal. The information terminal 5500 includes a housing 5510 and a display portion 5511. As input interfaces, a touch panel is provided in the display portion 5511 and a button is provided in the housing 5510.

By using the information processing device of one embodiment of the present invention, the information terminal 5500 can retain a temporary file generated at the time of executing an application (e.g., a web browser's cache).

FIG. 20B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application, by using the information processing device of one embodiment of the present invention.

FIG. 20C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application, by using the information processing device of one embodiment of the present invention.

Note that although FIG. 20A to FIG. 20C illustrate a smartphone, a wearable terminal, and a desktop information terminal as examples of the electronic device, one embodiment of the present invention can also be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

FIG. 20D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is compatible with IoT.

The information processing device of one embodiment of the present invention can be used in the electric refrigerator-freezer 5800. The electric refrigerator-freezer 5800 can transmit and receive information on food stored in the electric refrigerator-freezer 5800 and food expiration dates, for example, to/from an information terminal and the like via the Internet or the like. In the electric refrigerator-freezer 5800, the storage device included in the information processing device can retain a temporary file generated at the time of transmitting the information.

Here, an electric refrigerator-freezer is described as an example of a household appliance; other examples of household appliances include a vacuum, a microwave oven, an electric oven, a rice cooker, a water heater, an IH cooker, a water server, a heating-cooling combination appliance such as an air conditioner, a washing machine, a drying machine, and an audio visual appliance.

FIG. 20E illustrates a portable game machine 5200 as an example of a game machine. The portable game machine 5200 includes a housing 5201, a display portion 5202, a button 5203, and the like.

FIG. 20F illustrates a stationary game machine 7500 as another example of a game machine. The stationary game machine 7500 includes a main body 7520 and a controller 7522. The controller 7522 can be connected to the main body 7520 with or without a wire. Although not illustrated in FIG. 20F, the controller 7522 can include a display portion that displays a game image, and an input interface besides a button, such as a touch panel, a stick, a rotating knob, and a sliding knob, for example. The shape of the controller 7522 is not limited to that in FIG. 20F and may be changed variously in accordance with the genres of games. For example, in a shooting game such as an FPS (First Person Shooter) game, a gun-shaped controller having a trigger button can be used. For another example, in a music game or the like, a controller having a shape of a music instrument, audio equipment, or the like can be used. Furthermore, the stationary game machine may include a camera, a depth sensor, a microphone, and the like so that the game player can play a game using a gesture and/or a voice instead of a controller.

Videos for the game machine can be output with a display device such as a television device, a personal computer display, a game display, and a head-mounted display.

By using the information processing device described in the above embodiment in the portable game machine 5200 or the stationary game machine 7500, low power consumption can be achieved in the portable game machine 5200 or the stationary game machine 7500. Moreover, heat generation from a circuit can be reduced owing to low power consumption; thus, the influence of heat generation on the circuit itself, the peripheral circuit, and the module can be reduced.

Moreover, with the use of the information processing device described in the above embodiment, the portable game machine 5200 or the stationary game machine 7500 can retain a temporary file or the like necessary for an arithmetic operation that occurs during game play.

As examples of game machines, FIG. 20E illustrates a portable game machine. FIG. 20F illustrates a home-use stationary game machine. The electronic device of one embodiment of the present invention is not limited thereto. Other examples of the electronic device of one embodiment of the present invention include an arcade game machine installed in an entertainment facility (e.g., a game center and an amusement park) and a throwing machine for batting practice, installed in sports facilities.

The information processing device described in the above embodiment can be used in an automobile, which is a moving object, and around the driver's seat in an automobile.

FIG. 20G illustrates an automobile 5700 as an example of a moving object.

An instrument panel that provides various kinds of information by displaying a speedometer, a tachometer, a mileage, a fuel meter, a gearshift indicator, air-conditioning settings, and the like is provided around the driver's seat in the automobile 5700. In addition, a display device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety.

That is, displaying an image taken by the imaging device provided on the exterior of the automobile 5700 leads to compensation for the blind areas and an increase in safety.

The information processing device described in the above embodiment can temporarily retain information, and thus can be used to retain temporary information necessary in an automatic driving system for the automobile 5700 and a system for navigation and risk prediction, for example. The display device may be configured to display temporary information for navigation, risk prediction, and the like. Moreover, the information processing device may be configured to retain a video taken by a driving recorder provided on the automobile 5700.

Although an automobile is described above as an example of the moving object, the moving object is not limited to an automobile. Other examples of the moving object include a train, a monorail train, a ship, and a flying object (a helicopter, an unmanned aircraft (a drone), an airplane, and a rocket).

The information processing device described in the above embodiment can be used in a camera.

FIG. 20H illustrates a digital camera 6240 as an example of an imaging device. The digital camera 6240 includes a housing 6241, a display portion 6242, operation switches 6243, a shutter button 6244, and the like. An attachable lens 6246 is attached to the digital camera 6240. Here, the lens 6246 of the digital camera 6240 is detachable from the housing 6241 for replacement; alternatively, the lens 6246 may be incorporated into the housing 6241. Moreover, the digital camera 6240 may be configured to be equipped with a stroboscope, a viewfinder, or the like.

By using the information processing device described in the above embodiment in the digital camera 6240, low power consumption can be achieved in the digital camera 6240. Moreover, heat generation from a circuit can be reduced owing to low power consumption; thus, the influence of heat generation on the circuit itself, the peripheral circuit, and the module can be reduced.

The information processing device described in the above embodiment can be used in a video camera.

FIG. 20I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided for the first housing 6301, and the display portion 6303 is provided for the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded based on a data recording format. With the use of the above information processing device, the video camera 6300 can retain a temporary file generated in encoding.

The information processing device described in the above embodiment can be used in an implantable cardioverter-defibrillator (ICD).

FIG. 20J is a schematic cross-sectional view illustrating an example of an ICD. An ICD main unit 5400 includes at least a battery 5401, the electronic component 4700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of them placed in the right ventricle and the end of the other placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor or the like, the number of times the treatment with pacing is performed, and the time taken for the treatment, for example, can be stored in the electronic component 4700.

The antenna 5404 can receive power, and the power is charged into the battery 5401. When the ICD main unit 5400 includes a plurality of batteries, the safety can be improved. Specifically, even if one of the batteries in the ICD main unit 5400 is dead, the other batteries can work properly; hence, the batteries also function as an auxiliary power source.

In addition to the antenna 5404 capable of receiving power, an antenna that can transmit physiological signals may be included to construct, for example, a system that monitors the cardiac activity by checking physiological signals such as a pulse, a respiratory rate, a heart rate, and body temperature with an external monitoring device.

The information processing device described in the above embodiment can be used in a calculator such as a PC and an expansion device for an information terminal.

FIG. 21A illustrates, as an example of the expansion device, a portable expansion device 6100 that is externally attached to a PC and includes a chip capable of storing information. When the expansion device 6100 is connected to a PC with a USB (Universal Serial Bus), for example, information can be stored in the chip. FIG. 21A illustrates the portable expansion device 6100; however, the expansion device of one embodiment of the present invention is not limited to this and may be a relatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the information processing device or the like described in the above embodiment. For example, the substrate 6104 is provided with the electronic component 4700 and a controller chip 6106. The USB connector 6103 functions as an interface for connection to an external device.

The information processing device described in the above embodiment can be used in an SD card that can be attached to electronic devices such as an information terminal and a digital camera.

FIG. 21B is a schematic external view of an SD card, and FIG. 21C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with an information processing device. For example, the substrate 5113 is provided with the electronic component 4700 and a controller chip 5115. Note that the circuit structures of the electronic component 4700 and the controller chip 5115 are not limited to those described above and can be changed as appropriate depending on circumstances. For example, a writing circuit, a row driver, a reading circuit, and the like that are provided in an electronic component may be incorporated into the controller chip 5115 instead of the electronic component 4700.

When the electronic component 4700 is also provided on the back side of the substrate 5113, the capacity of the SD card 5110 can be increased. In addition, a wireless chip with a radio communication function may be provided on the substrate 5113. This enables wireless communication between an external device and the SD card 5110, making it possible to write/read data to/from the electronic component 4700.

The information processing device described in the above embodiment can be used in an SSD that can be attached to an electronic device such as an information terminal.

FIG. 21D is a schematic external view of an SSD, and FIG. 21E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with an information processing device. For example, the substrate 5153 is provided with the electronic component 4700, a memory chip 5155, and a controller chip 5156. When the electronic component 4700 is also provided on the back side of the substrate 5153, the capacity of the SSD 5150 can be increased. A work memory is incorporated into the memory chip 5155. For example, a DRAM chip is used as the memory chip 5155. A processor, an ECC circuit, and the like are incorporated into the controller chip 5156. Note that the circuit structures of the electronic component 4700, the memory chip 5155, and the controller chip 5156 are not limited to those described above and can be changed as appropriate depending on circumstances. For example, a memory functioning as a work memory may also be provided in the controller chip 5156.

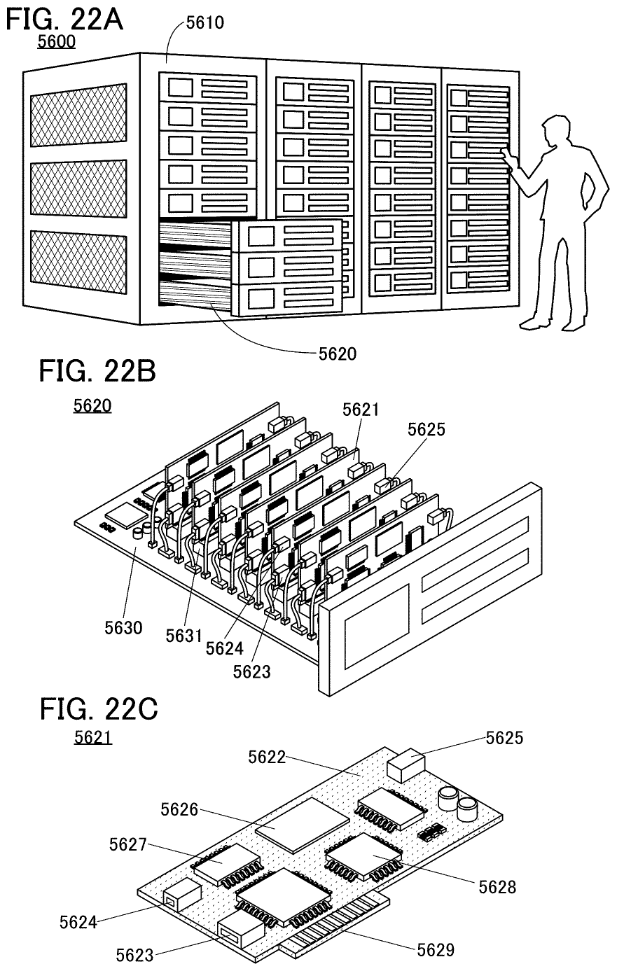

A computer 5600 illustrated in FIG. 22A is an example of a large computer. In the computer 5600, a plurality of rack mount computers 5620 are stored in a rack 5610. Note that the computer 5600 may be referred to as a supercomputer.

The computer 5620 can have a structure in a perspective view of FIG. 22B, for example. In FIG. 22B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 22C is an example of a processing board provided with a CPU, a GPU, an information processing device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 22C also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals. When the terminal is inserted in a socket (not illustrated) of the board 5622, the semiconductor device 5626 and the board 5622 can be electrically connected to each other.

The semiconductor device 5627 includes a plurality of terminals. When the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 4730 can be used, for example.

The semiconductor device 5628 includes a plurality of terminals. When the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 4700 can be used, for example.

The computer 5600 can also function as a parallel computer. When the computer 5600 is used as a parallel computer, large-scale computation necessary for artificial intelligence learning and inference can be performed, for example.

The information processing device of one embodiment of the present invention is used in a variety of electronic devices described above, whereby a smaller size, a higher speed, or lower power consumption of the electronic devices can be achieved. In addition, since the information processing device of one embodiment of the present invention has low power consumption, heat generation from a circuit can be reduced. Accordingly, it is possible to reduce adverse effects of the heat generation on the circuit itself, the peripheral circuit, and the module. Furthermore, the use of the information processing device of one embodiment of the present invention can achieve an electronic device that operates stably even in a high-temperature environment. Thus, the reliability of the electronic device can be improved.

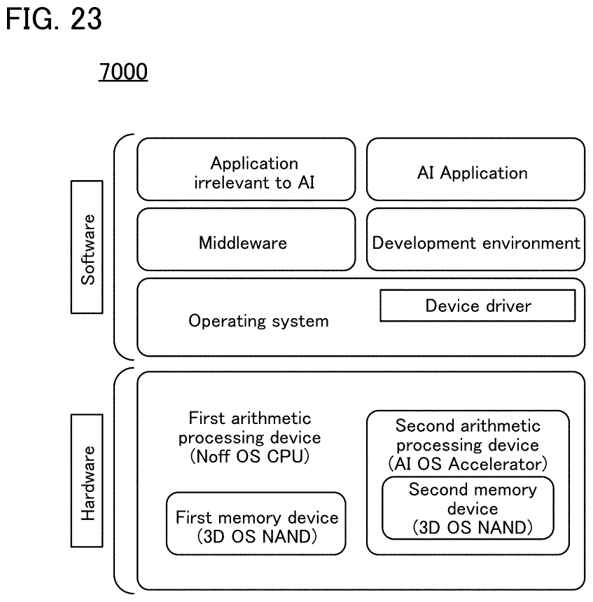

Next, a structure example of a computer system that can be used in the computer 5600 is described. FIG. 23 illustrates a structure example of a computer system 7000. The computer system 7000 is made of software and hardware. Note that the hardware included in the computer system is sometimes referred to as an information processing device.

Examples of the software in the computer system 7000 include operating systems including device drivers, middleware, a variety of development environments, application programs related to AI (AI Application), and application programs irrelevant to AI.

The device drivers include, for example, application programs for controlling externally connected devices such as an auxiliary storage device, a display device, and a printer.

The hardware in the computer system 7000 includes a first arithmetic processing device, a second arithmetic processing device, a first storage device, and the like. The second arithmetic processing device includes a second storage device.

As the first arithmetic processing device, a central arithmetic processing device such as an Noff OS CPU is preferably used, for example. The Noff OS CPU includes a storage means using OS transistors (e.g., a nonvolatile memory), and has a function of storing necessary information in the storage means and stopping power supply to the central arithmetic processing device when it does not need to operate. The use of the Noff OS CPU as the first arithmetic processing device can reduce the power consumption of the computer system 7000.

As the second arithmetic processing device, a GPU or an FPGA can be used, for example. Note that as the second arithmetic processing device, an AI OS Accelerator is preferably used. The AI OS Accelerator is composed of OS transistors and includes an arithmetic means such as a product-sum operation circuit. The power consumption of the AI OS Accelerator is lower than that of a common GPU and the like. The use of the AI OS Accelerator as the second arithmetic processing device can reduce the power consumption of the computer system 7000.

As the first arithmetic processing device and the second arithmetic processing device, the information processing device of one embodiment of the present invention is preferably used. For example, the information processing device including a 3D OS NAND storage device is preferably used. The 3D OS NAND storage device can function as a cache, a main memory, and storage. The use of the information processing device including the 3D OS NAND storage device facilitates fabrication of a non-von Neumann computer system.

When the semiconductor device constituting the hardware is configured with the semiconductor device including OS transistors, the hardware including the central arithmetic processing device, the arithmetic processing device, and the storage device can be easily monolithic. Making the hardware monolithic facilitates a further reduction in power consumption as well as a reduction in size, weight, and thickness.

The information processing device of one embodiment of the present invention can be suitably used for a small-scale system such as an IoT terminal device (also referred to as an endpoint microcomputer) in the IoT field, for example.

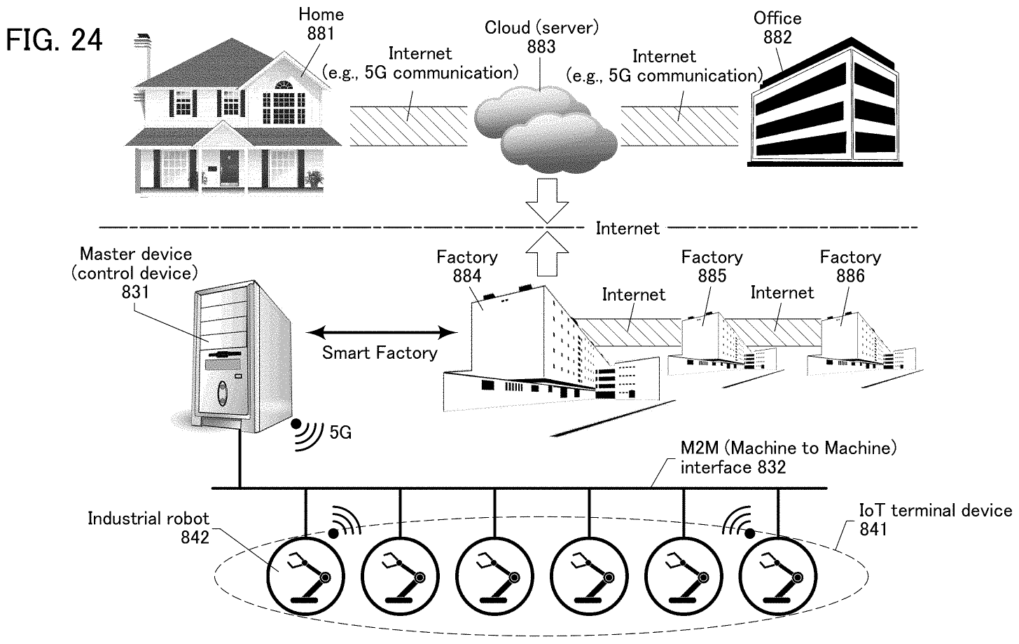

FIG. 24 shows a conceptual diagram showing factory automation as an application example of the endpoint microcomputer. A factory 884 is connected to a cloud 883 through Internet connection (Internet). The cloud 883 is connected to a home 881 and an office 882 through the Internet connection. The Internet connection may be wired communication or wireless communication. In the case of wireless communication, for example, wireless communication based on a communication standard such as the fourth-generation mobile communication system (4G) or the fifth-generation mobile communication system (5G) is performed using the information processing device of one embodiment of the present invention in a communication device. The factory 884 may be connected to a factory 885 and a factory 886 through the Internet connection.

The factory 884 includes a master device (control device) 831. The master device 831 is connected to the cloud 883 and has a function of transmitting and receiving information. The master device 831 is connected to a plurality of industrial robots 842 included in an IoT terminal device 841 through an M2M (Machine-to-Machine) interface 832. As the M2M interface 832, for example, industrial Ethernet (“Ethernet” is a registered trademark), which is a kind of wired communication, or local 5G, which is a kind of wireless communication, may be used.

A factory manager can check the operational status or the like from the home 881 or the office 882 connected to the factory 884 through the cloud 883. In addition, the manager can check wrong items and part shortage, instruct a storage space, and measure takt time, for example.

In recent years, IoT has been globally introduced into factories, under the name “Smart Factory”. Smart Factory has been reported to enable not only simple examination and inspection by an endpoint microcomputer but also detection of failures and prediction of abnormality, for example.

The total power consumption of a small-scale system such as an endpoint microcomputer during operation is often small, which enhances the power reduction effect in a standby state. Although the embedded field of IoT sometimes requires quick response, the use of the information processing device of one embodiment of the present invention allows high-speed return from a standby state.

Note that this embodiment can be combined with any of the other embodiments in this specification as appropriate.

(Supplementary Notes on Description in this Specification and the Like)

The description of the above embodiments and each structure in the embodiments are noted below.

One embodiment of the present invention can be constituted by combining, as appropriate, the structure described in each embodiment with the structures described in the other embodiments and Example. In addition, in the case where a plurality of structure examples are described in one embodiment, the structure examples can be combined as appropriate.

Note that content (or part of the content) described in one embodiment can be applied to, combined with, or replaced with another content (or part of the content) described in the embodiment and/or content (or part of the content) described in another embodiment or other embodiments, for example.

Note that in each embodiment, a content described in the embodiment is a content described with reference to a variety of drawings or a content described with text disclosed in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in the specification, and the description can be changed appropriately depending on the situation.

In drawings, the size, the layer thickness, or the region is shown arbitrarily for description convenience. Therefore, they are not limited to the illustrated scale. Note that the drawings are schematically shown for clarity, and embodiments of the present invention are not limited to shapes, values, or the like shown in the drawings. For example, variation in signal, voltage, or current due to noise or variation in signal, voltage, or current due to difference in timing can be included.

Furthermore, the positional relationship between components illustrated in the drawings and the like is relative. Therefore, when the components are described with reference to drawings, terms for describing the positional relationship, such as “over” and “under”, are sometimes used for convenience. The positional relationship of the components is not limited to that described in this specification and can be explained with other terms as appropriate depending on the situation.

In this specification and the like, the expressions “one of a source and a drain” (or a first electrode or a first terminal) and “the other of the source and the drain” (or a second electrode or a second terminal), which is for the other of the source and the drain, are used to describe the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, voltage and potential can be replaced with each other as appropriate. The voltage refers to a potential difference from a reference potential, and when the reference potential is a ground voltage, for example, the voltage can be rephrased into the potential. The ground potential does not necessarily mean 0 V. Note that potentials are relative, and the potential supplied to a wiring or the like is changed depending on the reference potential, in some cases.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

In this specification and the like, a switch has a function of controlling whether a current flows or not by being in a conduction state (an on state) or a non-conduction state (an off state). Alternatively, a switch has a function of selecting and changing a current path.

In this specification and the like, a channel length refers to, for example, the distance between a source and a drain in a region where a semiconductor (or a portion where a current flows in a semiconductor when a transistor is in an on state) and a gate overlap with each other or a region where a channel is formed in a top view of the transistor.

In this specification and the like, a channel width refers to, for example, the length of a portion where a source and a drain face each other in a region where a semiconductor (or a portion where a current flows in a semiconductor when a transistor is in an on state) and a gate electrode overlap with each other or a region where a channel is formed.

Note that in this specification and the like, the terms “film”, “layer”, and the like can be interchanged with each other depending on the case or according to circumstances. For example, the term “conductive layer” can be changed into the term “conductive film” in some cases. For another example, the term “insulating film” can be changed into the term “insulating layer” in some cases.

### REFERENCE NUMERALS

SCL1: scribe line, SCL2: scribe line, T1: period, T2: period, T3: period, T4: period, T5: period, T6: period, T7: period, T8: period, T9: period, 10: layer, 20: layer, 20_k: layer, 20_t: layer, 20_1: layer, 30: layer, 40: layer, 100: information processing device, 100A: information processing device, 110: information processing device, 110M: information processing device, 150: host, 200A: information processing device, 211: insulator, 212: insulator, 213: insulator, 214: insulator, 215: insulator, 216: insulator, 221: conductor, 222: conductor, 223: conductor, 231: semiconductor, 232: semiconductor, 240: insulator, 241: insulator, 242: insulator, 250: conductor, 251: conductor, 252: conductor, 300: transistor, 300A: information processing device, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 410: storage element, 411: transistor, 412: transistor, 413: node, 421: terminal, 422: terminal, 423: terminal, 425: capacitor, 431: transistor, 432: transistor, 433: terminal, 434: terminal, 690: integrated circuit, 693: bus, 694: host controller, 790: automobile, 791: camera, 792: imaging direction, 831: master device, 832: interface, 841: IoT terminal device, 842: industrial robot, 881: home, 882: office, 883: cloud, 884: factory, 885: factory, 886: factory, 901: boundary region, 902: boundary region, 4700: electronic component, 4702: printed circuit board, 4704: mounting board, 4710: information processing device, 4711: mold, 4712: land, 4713: electrode pad, 4714: wire, 4730: electronic component, 4731: interposer, 4732: package substrate, 4733: electrode, 4735: semiconductor device, 4800: semiconductor wafer, 4800a: chip, 4801: wafer, 4801a: wafer, 4802: circuit portion, 4803: spacing, 4803a: spacing, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 7000: computer system, 7500: stationary game machine, 7520: main body, 7522: controller

1. An information processing device comprising:
a storage device; and
an arithmetic device,
wherein the storage device comprises a first layer and a second layer,
wherein the first layer is provided with a circuit,
wherein the second layer is provided with a memory cell portion,
wherein the circuit is configured to switch and perform reading or writing of first data or second data from or to the memory cell portion,
wherein the memory cell portion is configured to retain the first data or the second data stored written, without power supply,
wherein at least part of the second layer is stacked above the first layer,
wherein the arithmetic device is provided in the first layer,
wherein the arithmetic device comprises a central processing device and an accelerator, and
wherein the accelerator is configured to execute a product-sum operation for performing inference processing based on a neural network.

2. The information processing device according to claim 1,
wherein the circuit comprises a data writing circuit and a data reading circuit,
wherein the data writing circuit comprises a first writing circuit which is configured to write the first data and a second writing circuit which is configured to write the second data, and
wherein the data reading circuit comprises a first reading circuit which is configured to read the first data and a second reading circuit which is configured to read the second data.

3. The information processing device according to claim 1,
wherein the first data is binary data, and
wherein the second data is data having three or more values.

4. The information processing device according to claim 1,
wherein the first layer comprises an SOI substrate,
wherein the circuit comprises a first transistor formed on the SOI substrate,
wherein the memory cell portion comprises a second transistor, and
wherein the second transistor comprises a metal oxide in a channel formation region.

5. The information processing device according to claim 1,
wherein the first layer comprises a single crystal silicon substrate,
wherein the circuit comprises a first transistor on the single crystal silicon substrate,
wherein the memory cell portion comprises a second transistor, and
wherein the second transistor comprises a metal oxide in a channel formation region.

6. A supercomputer comprising:
the information processing device according to claim 1; and
a plurality of switchboards,
wherein the information processing device is electrically connected to the plurality of switchboards.
